(19) United States
(12) Patent Application Publication
(10) Pub. No.: US 2026/0344036 A1
(43) Pub. Date: Oct. 29, 2026

(54) GATE STRUCTURE AND METHODS THEREOF

(71) Applicant: Taiwan Semiconductor Manufacturing Company, Ltd., Hsinchu (TW)

(72) Inventors: Chun Hao Liao, Hsinchu City (TW); Chu Fu Chen, Hsinchu County (TW); Yu-Ting Cheng, Hsinchu City (TW); Chan-yu Hung, Tainan City (TW)

(21) Appl. No.: 19/347,061

(22) Filed: Oct. 1, 2025

Related U.S. Application Data
(60) Provisional application No. 63/793,322, filed on Apr. 23, 2025.

(51) Int. Cl. H10D 84/85; H10D 30/00; H10D 30/01; H10D 30/43; H10D 30/62; H10D 62/10; H10D 62/13; H10D 84/01

(52) U.S. Cl. CPC H10D 84/854; H10D 30/014; H10D 30/019; H10D 30/024; H10D 30/027; H10D 30/43; H10D 30/502; H10D 30/6211; H10D 30/6212; H10D 62/121; H10D 62/151; H10D 84/0172; H10D 84/0181; H10D 84/0186; H10D 84/851; H10D 84/853

(57) ABSTRACT

A method and structure providing a semiconductor device including a first device region having a non-planar device. The non-planar device includes a first active region extending in a first direction, an isolation feature extending in the first direction and disposed alongside the first active region, and a first gate including a gate dielectric layer, the first gate extending in a second direction over the first active region and the isolation feature, the second direction different from the first direction. The semiconductor device further includes a second device region having a first device. The first device includes a second active region extending in the second direction and a second gate extending in the first direction. A dielectric constant of the gate dielectric layer is greater than a dielectric constant of the isolation feature. The non-planar device is configured to be operated at a same or lower voltage than the first device.

### CROSS-REFERENCE TO RELATED APPLICATION

This application claims the benefit of U.S. Provisional Application No. 63/793,322, filed Apr. 23, 2025, the entirety of which is incorporated by reference herein.

### BACKGROUND

The electronics industry has experienced an ever increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Recently, multi-gate devices (or non-planar devices) have been introduced in an effort to improve gate control by increasing gate-channel coupling, reduce OFF-state current, and reduce short-channel effects (SCEs). One such non-planar device that has been introduced is the fin field-effect transistor (FinFET). The FinFET gets its name from the fin-like structure which extends from a substrate on which it is formed, and which is used to form the FET channel. Another non-planar device, introduced in part to address performance challenges associated with FinFETs, is the gate-all-around (GAA) transistor. GAA transistors get their name from the gate structure which extends completely around the channel, providing better electrostatic control than FinFETs. FinFETs and GAA transistors are compatible with conventional complementary metal-oxide-semiconductor (CMOS) processes and their three-dimensional structure allows them to be aggressively scaled while maintaining gate control and mitigating SCEs.

Non-planar devices, such as FinFETs and GAA transistors, may at times be used in conjunction with transistors that operate at higher voltages, such as medium voltage (MV) transistors and high voltage (HV) transistors. In some examples, the non-planar devices and MV/HV transistors may be used to collectively provide various types of integrated circuit (IC) devices. However, portions of IC devices that include the MV/HV transistors occupy a large area of the substrate, adding to design and processing challenges, especially as the performance requirements of IC devices continues to advance. Thus, existing processes have not proved entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is perspective view of a planar transistor, in accordance with some embodiments;

FIG. 1B is perspective view of a non-planar transistor, in accordance with some embodiments;

FIG. 2A is simplified top-down layout view of a non-planar transistor, in accordance with some embodiments;

FIG. 2B is simplified top-down layout view of a planar transistor, in accordance with some embodiments;

FIG. 3A provides a top-down view of a multi-voltage IC device, in accordance with some embodiments;

FIG. 3B provides a cross-section view of the multi-voltage IC device of FIG. 3A, in accordance with some embodiments;

FIG. 4A provides a top-down view of another multi-voltage IC device, in accordance with some embodiments;

FIG. 4B provides a cross-section view of the multi-voltage IC device of FIG. 4A, in accordance with some embodiments;

FIG. 5 provides a top-down view of still another multi-voltage IC device, in accordance with some embodiments;

FIG. 6 illustrates an exemplary design house operable to perform a design procedure to generate a target layout design of a multi-voltage IC device, in accordance with some embodiments;

FIG. 7 provides a flowchart of a method for generating a layout design for a multi-voltage IC device, in accordance with some embodiments;

FIG. 8 provides a flowchart of a method for fabrication of non-planar devices, in accordance with some embodiments;

FIGS. 9A, 10A, 11A, 12A and 13A provide isometric views of a first non-planar device at different stages of fabrication of the method of FIG. 8, in accordance with some embodiments;

FIGS. 12C and 13C provide cross-section views of the first non-planar device at different stages of fabrication of the method of FIG. 8 along a plane parallel to section X1-X1′ of FIG. 12A, in accordance with some embodiments;

FIGS. 12E, 13E, and 13G provide cross-section views of the first non-planar device at different stages of fabrication of the method of FIG. 8 along a plane parallel to section Y1-Y1′ of FIG. 12A, in accordance with some embodiments;

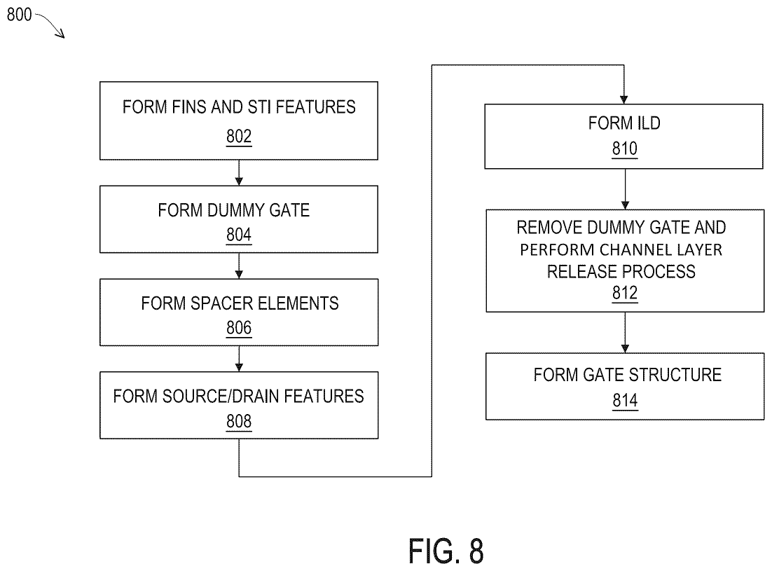

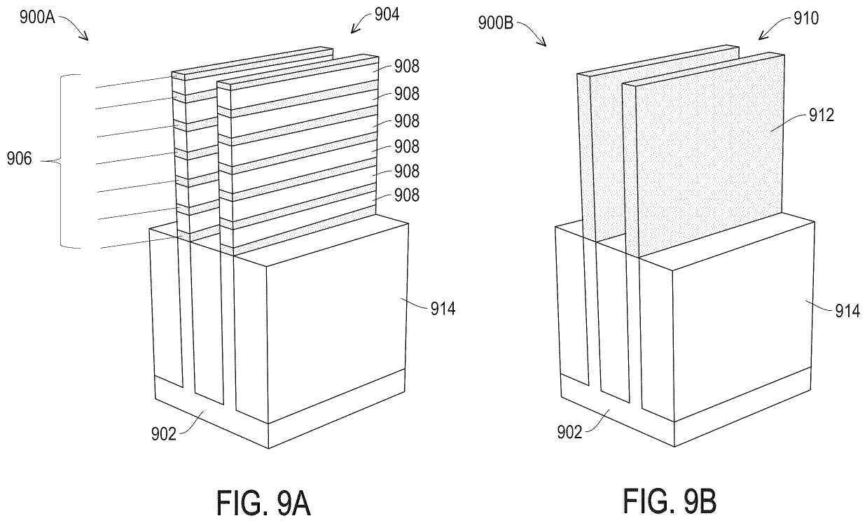

FIGS. 9B, 10B, 11B, 12B and 13B provide isometric views of a second non-planar device at different stages of fabrication of the method of FIG. 8, in accordance with some embodiments;

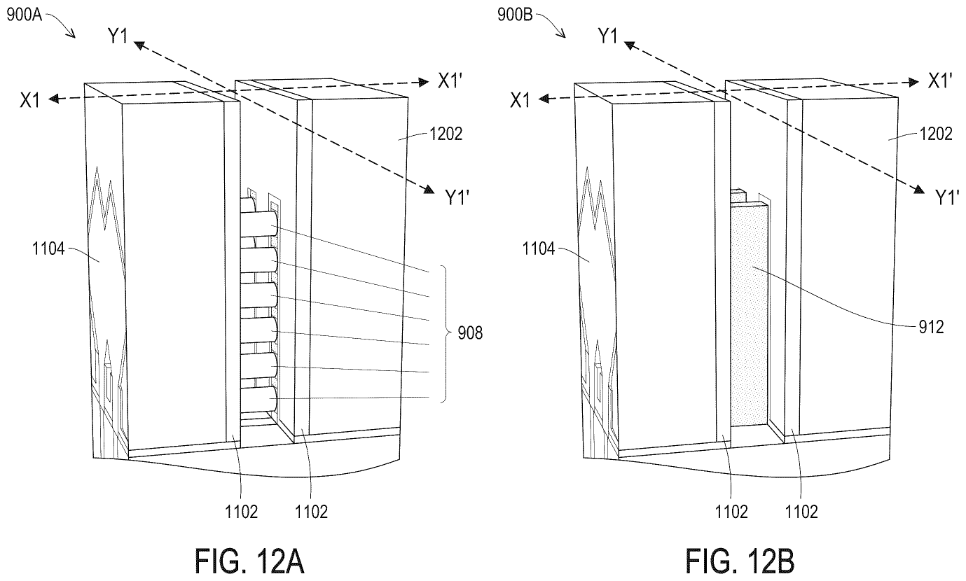

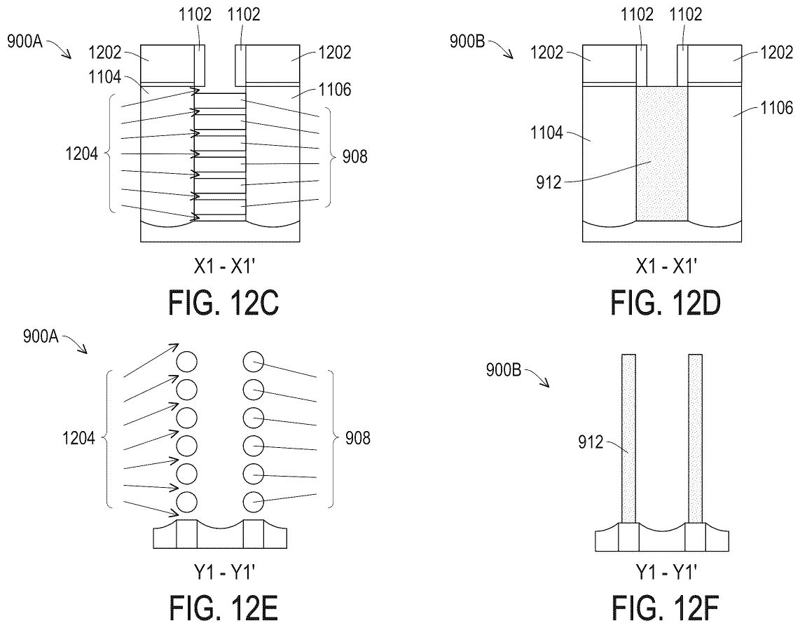

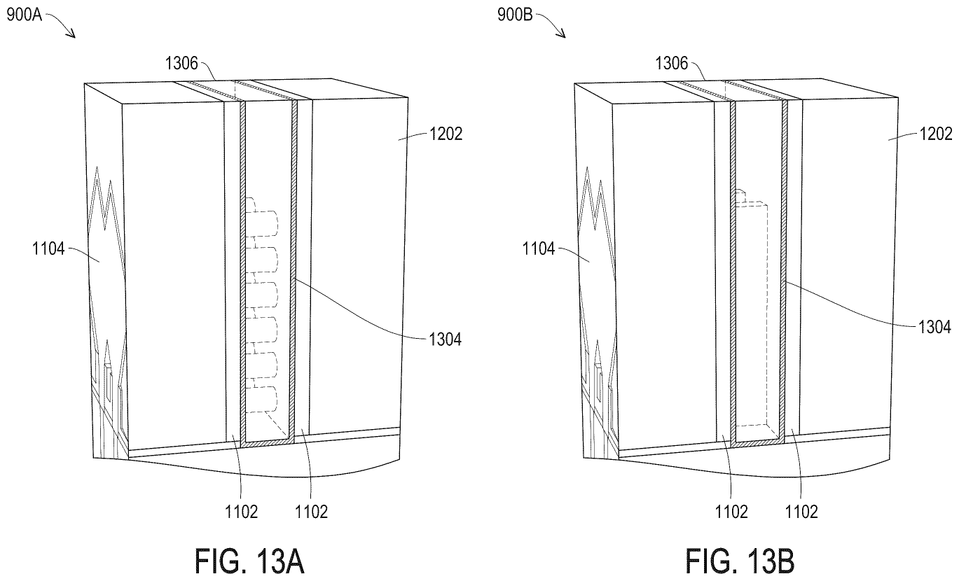

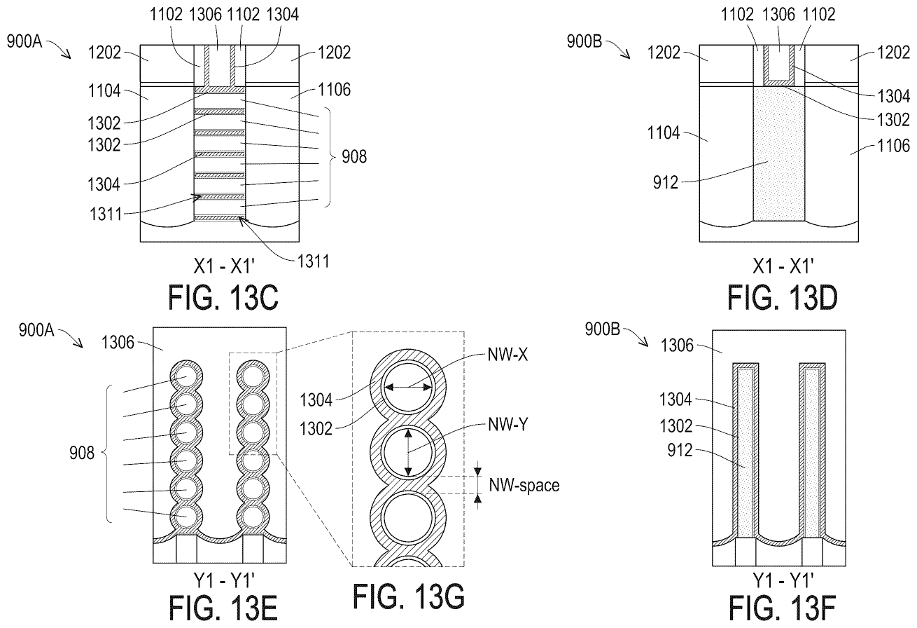

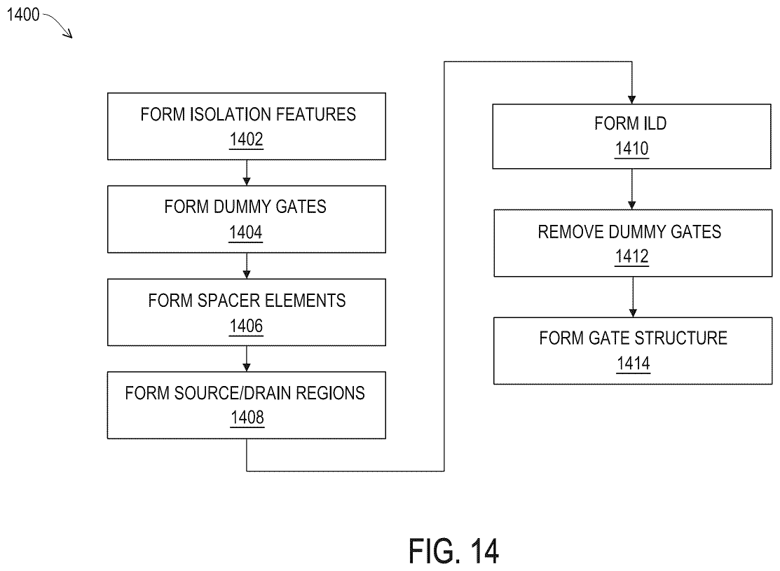

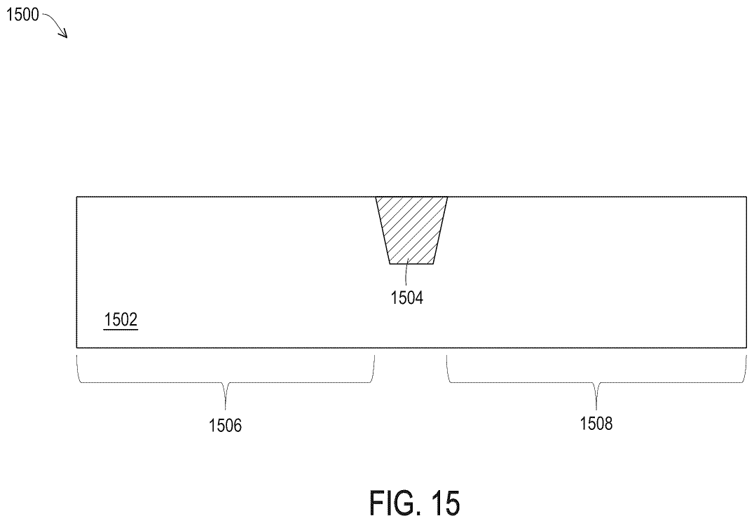

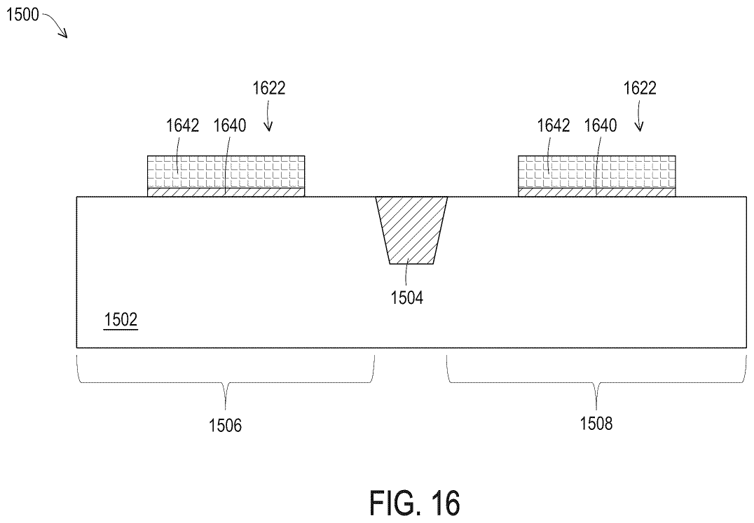

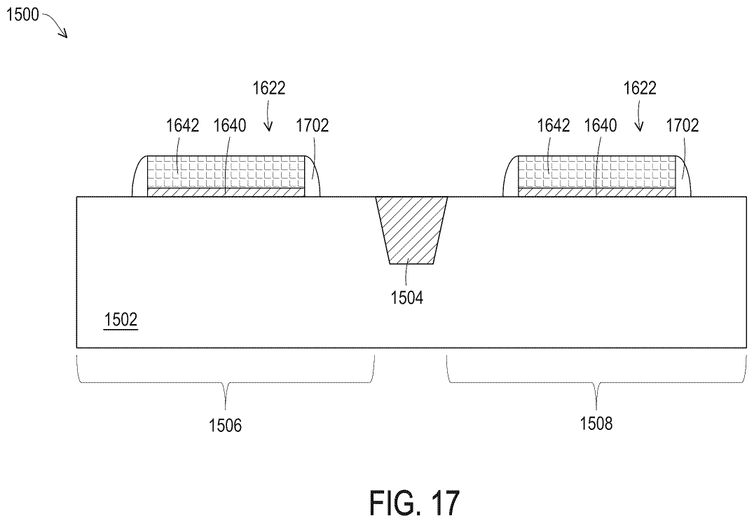

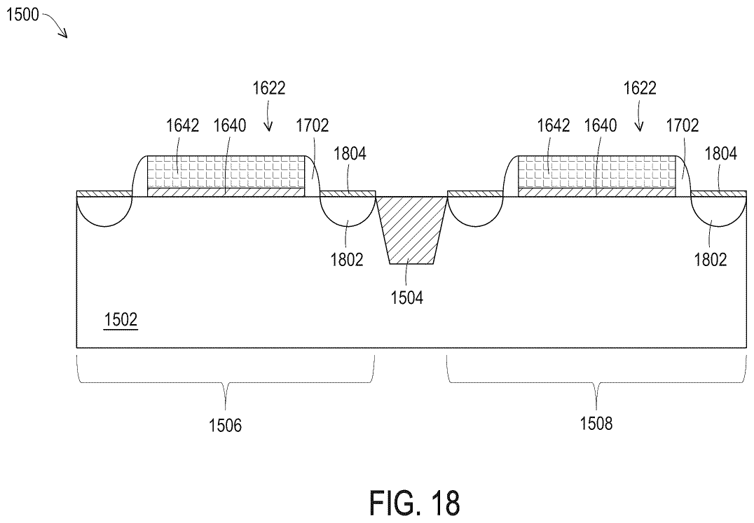

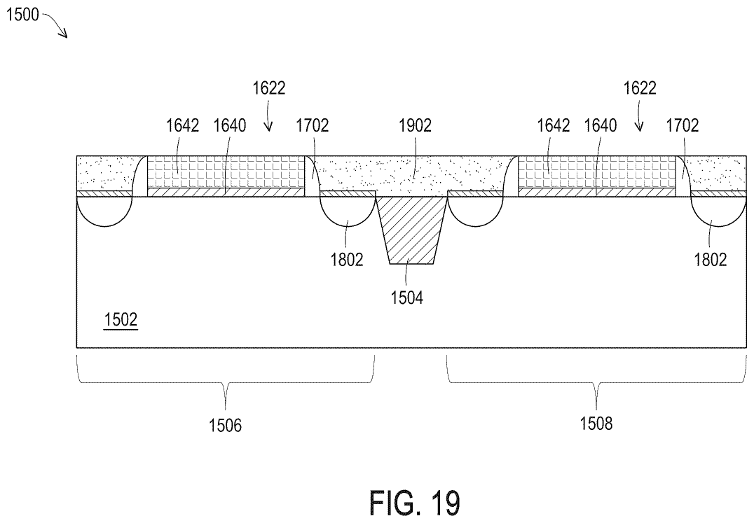

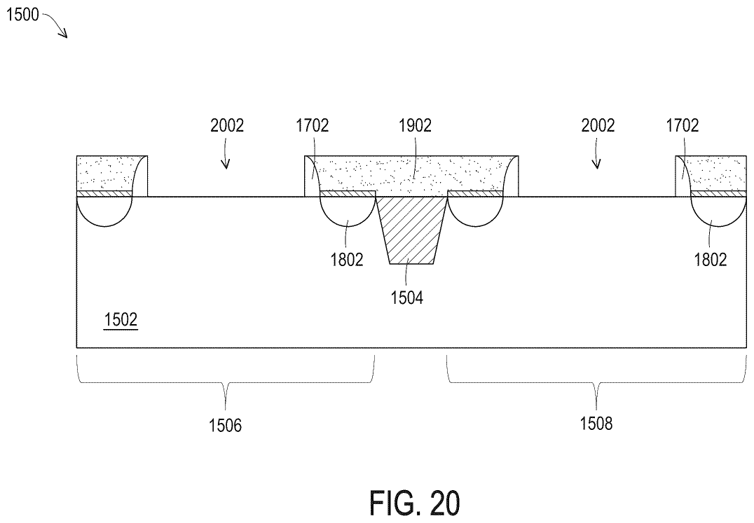

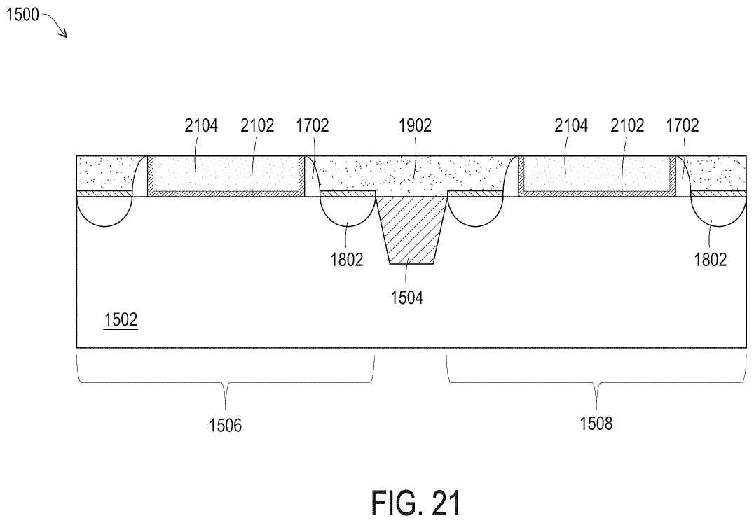

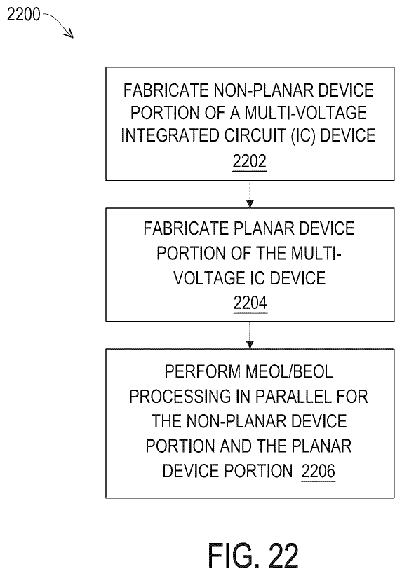

FIGS. 12D and 13D provide cross-section views of the second non-planar device at different stages of fabrication of the method of FIG. 8 along a plane parallel to section X1-X1′ of FIG. 12B, in accordance with some embodiments;

FIGS. 12F and 13F provide cross-section views of the second non-planar device at different stages of fabrication of the method of FIG. 8 along a plane parallel to section Y1-Y1′ of FIG. 12B, in accordance with some embodiments;

FIG. 14 provides a flowchart of a method for fabrication of planar devices, in accordance with some embodiments;

FIGS. 15, 16, 17, 18, 19, 20, and 21 provide cross-section views of a planar device at different stages of fabrication of the method of FIG. 14, in accordance with some embodiments; and

FIG. 22 provides a flowchart of a method for fabrication of a multi-voltage integrated circuit (IC) device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Additionally, in the discussion that follows, dimensions (e.g., such as thickness, width, length, etc.) for a given layer or other feature may at times be described using terms such as “substantially equal”, “equal”, or “about”, where such terms are understood to mean within +/−10% of the recited value or between compared values. For instance, if dimension A is described as being “substantially equal” to dimension B, it will be understood that dimension A is within +/−10% of dimension B. As another example, if a layer is described as having a thickness of about 100 nm, it will be understood that the thickness of the layer may in a range between 90-110 nm. To be sure, in some embodiments, the terms such as “substantially equal”, “equal”, or “about” may alternatively be understood to mean within a different percentage or range of the recited value, not limited to +/−10%, where such a different percentage or range may be known by those skilled in the art and may be dependent on various process, material, and/or device conditions or features.

It is also noted that the present disclosure presents embodiments which may be implemented using any of a variety of semiconductor device types. For example, embodiments of the present disclosure may be implemented using multi-gate devices such as FinFET devices, gate-all-around (GAA) devices, Omega-gate (Ω-gate) devices, or Pi-gate (II-gate) devices, planar bulk metal-oxide-semiconductor field-effect transistors (MOSFETs), forksheet devices, strained-semiconductor devices, silicon-on-insulator (SOI) devices, partially-depleted SOI devices, fully-depleted SOI devices, or other devices as known in the art. For purposes of discussion, multi-gate devices may at times be more generally referred to as non-planar devices. In addition, embodiments disclosed herein may be implemented using P-type and/or N-type transistors. One of ordinary skill may recognize other embodiments of semiconductor devices that may be used to implement, and which may benefit from, aspects of the present disclosure.

The present disclosure generally relates to semiconductor structures including non-planar devices (e.g., such as FinFETs and/or GAA transistors) integrated on a same substrate with medium voltage (MV) transistors and/or high voltage (HV) transistors. The non-planar devices, in some examples, may also be referred to as low voltage (LV) transistors. In the disclosed embodiments, the MV/HV transistors may be implemented using planar field-effect transistors (planar FETs), as described in more detail below. In various embodiments, the non-planar devices and MV/HV transistors may be used to collectively provide various types of integrated circuit (IC) devices. While not limited thereto, and as one example, non-planar devices and MV/HV transistors may be integrated on a same substrate to provide a display driver IC (DDIC) device, which is configured to drive a display panel that displays an image. In addition to differences in device type (e.g., non-planar devices implemented as FinFETs and/or GAA transistors and MV/HV transistors implemented as planar FETs), the non-planar devices (LV transistors) and the MV/HV transistors may be implemented using different layer thicknesses (e.g., such as gate oxide thickness), material type, doping configuration, and/or other different transistor design features. In some embodiments, the non-planar devices (LV transistors) may be used to implement core/logic devices, memory devices (e.g., such as SRAM transistors), or other devices that operate using a substantially nominal voltage. In some cases, the MV/HV transistors may be used to implement a source driver, a gate driver, or other devices that operate using a higher voltage than the non-planar devices (LV transistors). The source driver and/or the gate driver may include an analog circuit, in some embodiments. For purposes of this disclosure, an IC device structure that includes both non-planar devices and MV/HV transistors may be referred to as a multi-voltage IC device, a multi-voltage circuit, or a multi-voltage semiconductor structure.

In some existing implementations, multi-voltage IC devices may occupy a large substrate area. This is largely due to portions of multi-voltage IC devices that include the MV/HV transistors occupying a large substrate area. This area limitation is due, at least in part, to the single device direction (orientation) that is used for the multi-voltage IC device, where both the non-planar device portion of the multi-voltage IC device and the MV/HV transistor portion of the multi-voltage IC device are oriented in the same direction. In some examples, the single device direction or orientation may refer to a transistor gate direction or orientation. In some cases, having the gate of a non-planar device (e.g., FinFET and/or GAA transistor) and the gate of a planar FET (used to implement the MV/HV transistors) oriented in the same direction results in increased substrate area consumption because of the differences in current that flow through each device type. For example, since planar FETs have fewer current paths (and/or less channel layers) than non-planar devices, the gate length of the planar FET (MV/HV transistors) can be 20× greater than the gate length of the non-planar device. Thus, orienting the non-planar device and the planar FETs (MV/HV transistors) in the same direction can result in the multi-voltage IC device occupying a large substrate area. These limitations add to design and processing challenges, especially as the performance requirements of IC devices continues to advance. Thus, existing processes have not proved entirely satisfactory in all respects.

Embodiments of the present disclosure offer advantages over the existing art, though it is understood that other embodiments may offer different advantages, not all advantages are necessarily discussed herein, and no particular advantage is required for all embodiments. For example, embodiments discussed herein include multi-voltage IC devices that overcome the challenges described above. In some embodiments, and in contrast to existing implementations, an orientation of the MV/HV transistor portion of the multi-voltage IC device may be rotated with respect to the non-planar device portion of the multi-voltage IC device. As a result, and in various embodiments, the gate of a non-planar device (e.g., FinFET and/or GAA transistor) of the non-planar device portion may be oriented in a first direction, and the gate of a planar FET of the MV/HV transistor portion may be oriented in a second direction different than the first direction. In at least some embodiments, the gate of a first non-planar device (e.g., FinFET and/or GAA transistor) of the non-planar device portion may be oriented in a first direction, and the gate of a second non-planar device (e.g., FinFET and/or GAA transistor) of the non-planar device portion may be oriented in a second direction different than the first direction. In such examples, the first and second non-planar devices may be configured to be operated at a same voltage. In some cases, the first direction is perpendicular to the second direction. However, more generally, the second direction may include any of a plurality of directions that are different from the first direction and which provide for reduced interconnect routing and/or improved design flexibility. In addition, and in some embodiments, a first gate-to-source/drain contact distance is defined for the non-planar device (e.g., FinFET and/or GAA transistor) of the non-planar device portion and a second gate-to-source/drain contact distance is defined for the planar FET of the MV/HV transistor portion. In general, and in various embodiments, the second gate-to-source/drain contact distance may be greater than the first gate-to-source/drain contact distance. However, due to the high exposure resolution in the first direction, the second gate-to-source/drain contact distance may be decreased (e.g., as compared to the second gate-to-source/drain contact distance in existing implementations) to save additional substrate area. Further, in some cases, a width of the source/drain contact of the rotated planar FET of the MV/HV transistor portion may be increased to provide reduced resistance. The various embodiments disclosed herein may be implemented without the need for an extra mask or extra process. The disclosed embodiments are robust, cost-effective, provide improved design flexibility, reduced interconnect routing, reduced substrate area coverage, reduced device resistance, and they are fully compatible with existing non-planar device process technology. Those skilled in the art will recognize other benefits and advantages of the methods and devices as described herein, and the embodiments described are not meant to be limiting beyond what is specifically recited in the claims that follow.

Generally, the devices and structures disclosed herein may be manufactured in a number of ways using a number of different tools. In some cases, the non-planar device portion of the multi-voltage IC device may be manufactured on a semiconductor substrate first, and the MV/HV transistor portion of the multi-voltage IC device may be manufactured thereafter on the same semiconductor substrate as the non-planar device portion. In some embodiments, both the non-planar device portion and the MV/HV transistor portion of the multi-voltage IC device may be manufactured at the same time on a same semiconductor substrate by using the same or similar processes. In various cases, the manufacturing processes and tools may be used to form structures having dimensions in the micrometer and/or nanometer scale (nanostructures). In some examples, the devices disclosed herein may be manufactured using IC fabrication technology, which may include features of a complementary metal-oxide-semiconductor (CMOS) technology process flow. For example, the devices and structures disclosed herein may be formed on substrates upon which thin films of material are deposited, patterned using a photolithography process, and selectively etched. Additional details regarding the manufacture of devices in the non-planar device portion and devices in the MV/HV transistor portion are provided below with respect to the method of FIGS. 8 and 14.

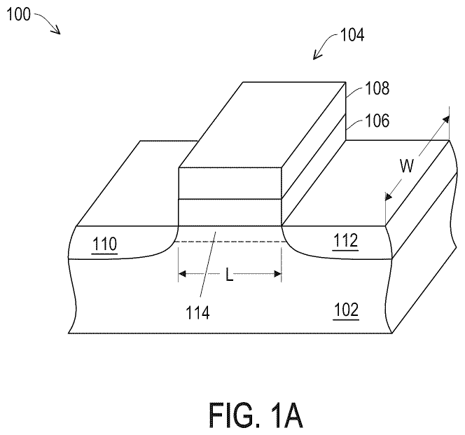

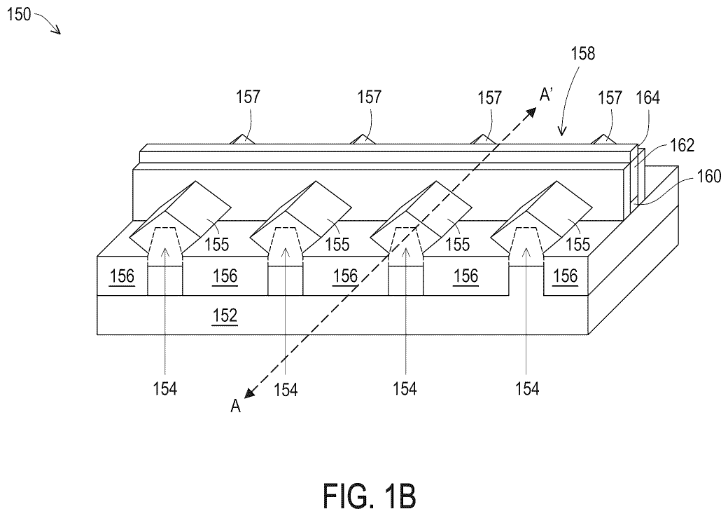

As previously described, the disclosed multi-voltage IC devices disclosed herein may be implemented using non-planar devices (e.g., such as FinFETs and/or GAA transistors) integrated on the same substrate as MV/HV transistors (e.g., implemented using planar FETs). To provide further details regarding the device structures used to implement these devices, reference is now made to FIG. 1A and FIG. 1B. Referring first to the example of FIG. 1A, illustrated therein is a planar FET 100, such as may be used to implement the MV/HV transistors. In various embodiments and depending on the particular device type being fabricated (e.g., MV transistor or HV transistor), various aspects of the planar FET 100 may be appropriately modified (e.g., layer thicknesses, material type, doping configuration, etc.). The planar FET 100 is fabricated on a substrate 102 and includes a gate stack 104. The substrate 102 may be a semiconductor substrate such as a silicon substrate. The substrate 102 may include various layers, including conductive or insulating layers formed on the substrate 102. The substrate 102 may include various doping configurations depending on design requirements as is known in the art. The substrate 102 may also include other semiconductors such as germanium, silicon carbide (SiC), silicon germanium (SiGe), or diamond. Alternatively, the substrate 102 may include a compound semiconductor and/or an alloy semiconductor. Further, in some embodiments, the substrate 102 may include an epitaxial layer (epi-layer), the substrate 102 may be strained for performance enhancement, the substrate 102 may include a silicon-on-insulator (SOI) structure, and/or the substrate 102 may have other suitable enhancement features.

The gate stack 104 includes a gate dielectric 106 and a gate electrode 108 disposed on the gate dielectric 106. In some embodiments, the gate dielectric 106 may include an interfacial layer such as silicon oxide layer (SiO₂) or silicon oxynitride (SiON), where such interfacial layer may be formed by chemical oxidation, thermal oxidation, atomic layer deposition (ALD), chemical vapor deposition (CVD), and/or other suitable method. In some examples, the gate dielectric 106 includes a high-K dielectric layer such as hafnium oxide (HfO₂). Alternatively, the high-K dielectric layer may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba, Sr)TiO₃ (BST), Al₂O₃, Si₃N₄, oxynitrides (SiON), combinations thereof, or other suitable material. High-K gate dielectrics, as used and described herein, include dielectric materials having a high dielectric constant, for example, greater than that of thermal silicon oxide (~3.9). In still other embodiments, the gate dielectric 106 may include silicon dioxide or other suitable dielectric. The gate dielectric 106 may be formed by ALD, physical vapor deposition (PVD), CVD, oxidation, and/or other suitable methods. In some embodiments, the gate electrode 108 may be deposited as part of a gate first or gate last (e.g., replacement gate) process. In various embodiments, the gate electrode 108 includes a conductive layer such as W, Ti, TiN, TiAl, TiAlN, Ta, TaN, WN, Re, Ir, Ru, Mo, Al, Cu, Co, CoSi, Ni, NiSi, combinations thereof, and/or other suitable compositions. In some examples, the gate electrode 108 may include a first metal material for an N-type transistor and a second metal material for a P-type transistor. Thus, the planar FET 100 may include a dual work-function metal gate configuration. For example, the first metal material (e.g., for N-type devices) may include metals having a work function substantially aligned with a work function of the substrate conduction band, or at least substantially aligned with a work function of the conduction band of a channel region 114 of the planar FET 100. Similarly, the second metal material (e.g., for P-type devices) may include metals having a work function substantially aligned with a work function of the substrate valence band, or at least substantially aligned with a work function of the valence band of the channel region 114 of the planar FET 100. Thus, the gate electrode 104 may provide a gate electrode for the planar FET 100, including both N-type and P-type devices. In some embodiments, the gate electrode 108 may alternately or additionally include a polysilicon layer. In various examples, the gate electrode 108 may be formed using PVD, CVD, electron beam (e-beam) evaporation, and/or other suitable process. In some embodiments, sidewall spacers are formed on sidewalls of the gate stack 104, where the sidewall spacers extend in a same direction as the gate stack 104. Such sidewall spacers may include a dielectric material such as silicon oxide, silicon nitride, silicon carbide, silicon oxynitride, or combinations thereof.

The planar FET 100 further includes a source region 110 and a drain region 112 each formed within the semiconductor substrate 102, adjacent to and on either side of the gate stack 104. In some embodiments, the source and drain regions 110, 112 include diffused source/drain regions, ion implanted source/drain regions, epitaxially grown regions, or a combination thereof. The channel region 114 of the planar FET 100 is defined as the region between the source and drain regions 110, 112 under the gate dielectric 106, and within the semiconductor substrate 102. The channel region 114 has an associated channel length “L” and an associated channel width “W”. When a bias voltage greater than a threshold voltage (Vₜ) (i.e., turn-on voltage) for the planar FET 100 is applied to the gate electrode 108 along with a concurrently applied bias voltage between the source and drain regions 110, 112, an electric current (e.g., a transistor drive current) flows between the source and drain regions 110, 112 through the channel region 114. The amount of drive current developed for a given bias voltage (e.g., applied to the gate electrode 108 or between the source and drain regions 110, 112) is a function of, among others, the mobility of the material used to form the channel region 114. In some examples, the channel region 114 includes silicon (Si) and/or a high-mobility material such as germanium, which may be epitaxially grown, as well as any of the plurality of compound semiconductors or alloy semiconductors as known in the art. High-mobility materials include those materials with electron and/or hole mobility greater than silicon (Si), which has an intrinsic electron mobility at room temperature (300 K) of around 1350 cm²/V-s and a hole mobility of around 480 cm²/V-s.

Referring now to the example of FIG. 1B, illustrated therein is a non-planar device 150, such as may be used to implement the non-planar devices (LV transistors). By way of example, the non-planar device 150 includes one or more non-planar field-effect transistors (FETs). In various embodiments, the non-planar device 150 may include a FinFET device or a GAA device. The non-planar device 150 includes a substrate 152, at least one fin element 154 extending from the substrate 152, isolation regions 156, and a gate structure 158 disposed on and around the fin-element 154. The substrate 152 may be a semiconductor substrate such as a silicon substrate. In various embodiments, the substrate 152 may be substantially the same as the substrate 102 and may include one or more of the materials used for the substrate 102, as described above.

The fin-element 154, like the substrate 152, may include one or more epitaxially-grown layers, and may comprise silicon or another elementary semiconductor, such as germanium; a compound semiconductor including silicon carbide, gallium arsenide, gallium phosphide, indium phosphide, indium arsenide, and/or indium antimonide; an alloy semiconductor including SiGe, GaAsP, AlInAs, AlGaAs, InGaAs, GaInP, and/or GaInAsP; or combinations thereof. The fin elements 154 may be fabricated using suitable processes including photolithography and etch processes. The photolithography process may include forming a photoresist layer (resist) overlying the substrate (e.g., on a silicon layer), exposing the resist to a pattern, performing post-exposure bake processes, and developing the resist to form a masking element including the resist. In some embodiments, pattering the resist to form the masking element may be performed using an electron beam (e-beam) lithography process. The masking element may then be used to protect regions of the substrate while an etch process forms recesses into the silicon layer, thereby leaving an extending fin 154. The recesses may be etched using a dry etch (e.g., chemical oxide removal), a wet etch, and/or other suitable processes. Numerous other embodiments of methods to form the fins 154 on the substrate 152 may also be used. It is also noted that when the non-planar device 150 includes a FinFET device, the fins 154 may include a continuous fin of substantially uniform composition, and when the non-planar device 150 includes a GAA device, the fins 154 may include a plurality of channels disposed in a plurality of semiconductor channel layers interposed by portions of the gate structure 158. In particular, when the non-planar device 150 includes a GAA device, the plurality of channel layers may be referred to as nanostructures, nanowires, nanobars, or nanosheets, which may include channel regions of various geometries and various dimensions.

Each of the plurality of fins 154 also include a source region 155 and a drain region 157 where the source/drain regions 155, 157 are formed in, on, and/or surrounding the fin 154. The source/drain regions 155, 157 may be epitaxially grown over the fins 154. In addition, a channel region of a transistor (or multiple channel regions, for the case of GAA transistors) is disposed within the fin 154, underlying the gate structure 158, along a plane substantially parallel to a plane defined by section AA′ of FIG. 1B. In some examples, the channel region of the fin includes a high-mobility material, as described above.

The isolation regions 156 may be shallow trench isolation (STI) features. Alternatively, a field oxide, a LOCOS feature, and/or other suitable isolation features may be implemented on and/or within the substrate 152. The isolation regions 156 may be composed of silicon oxide, silicon nitride, silicon oxynitride, fluorine-doped silicate glass (FSG), a low-k dielectric, combinations thereof, and/or other suitable material known in the art. In an embodiment, the isolation regions 156 are STI features and are formed by etching trenches in the substrate 152. The trenches may then be filled with isolating material, followed by a chemical mechanical polishing (CMP) process. However, other embodiments are possible. In some embodiments, the isolation regions 156 may include a multi-layer structure, for example, having one or more liner layers.

The gate structure 158 includes a gate stack having an interfacial layer 160 formed over the channel region of the fin 154, a gate dielectric layer 162 formed over the interfacial layer 160, and a metal layer 164 formed over the gate dielectric layer 162. In various embodiments, the interfacial layer 160 is substantially the same as the interfacial layer described as part of the gate dielectric 106. In some embodiments, the gate dielectric layer 162 is substantially the same as the gate dielectric 106 and may include high-K dielectrics similar to those used for the gate dielectric 106. It is also noted that the dielectric constant of the gate dielectric layer 162 may be greater than the dielectric constant of the isolation regions 156, in some examples. Similarly, in various embodiments, the metal layer 164 is substantially the same as the gate electrode 108, described above. In some embodiments, sidewall spacers are formed on sidewalls of the gate structure 158, where the sidewall spacers extend in a same direction as the gate structure 158. The sidewall spacers may include a dielectric material such as silicon oxide, silicon nitride, silicon carbide, silicon oxynitride, or combinations thereof.

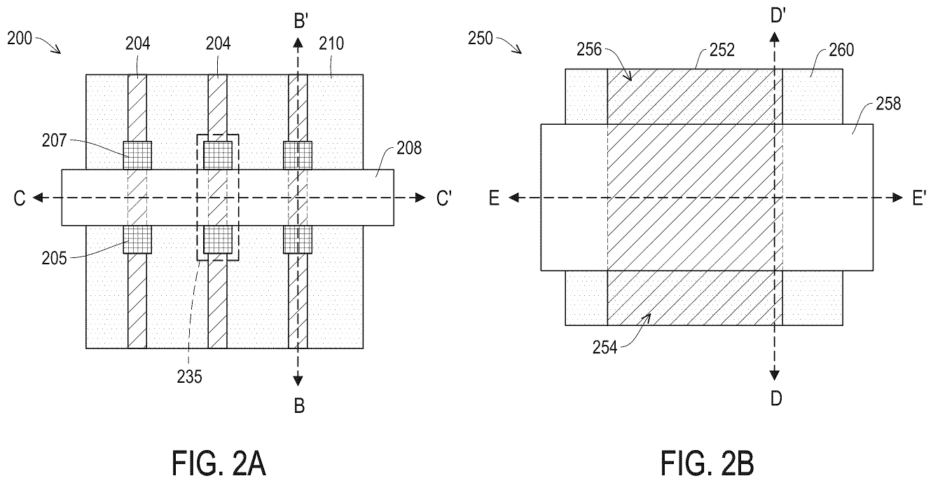

For purposes of the discussion that follows, reference is made to FIG. 2A and FIG. 2B, which provide simplified layout views of the planar FET 100 and the non-planar device 150, discussed above. FIG. 2A provides a simplified top-down layout view of a non-planar device 200, which may be substantially the same as the non-planar device 150, discussed above. The non-planar device 200 may include a plurality of fin elements 204 extending from a substrate, a gate structure 208 disposed over and around the fin elements 204 and over the isolation regions 210, and source/drain regions 205, 207, where the source/drain regions 205, 207 are formed in, on, and/or surrounding the fins 204. For purposes of this disclosure, and in some examples, the fin elements 204 may be equivalently referred to as active regions or fin-shaped active regions. In various embodiments, the fin elements 204 may be substantially the same as the fin elements 154, the gate structure 208 may be substantially the same as the gate structure 158, and source/drain regions 205, 207 may be substantially the same as the source/drain regions 155, 157, each of which has been discussed above with reference to the non-planar device 150 of FIG. 1B. A channel region of the non-planar device 200, which may include a plurality of semiconductor channel layers (e.g., when the non-planar device 200 includes a GAA transistor), is disposed within the fins 204, underlying the gate structure 208, along a plane substantially parallel to a plane defined by section BB′ of FIG. 2A. The non-planar device 200 also includes isolation regions 210, which may be substantially the same as the isolation regions 156 discussed above, and which may include STI features, in some cases. As shown, the isolation regions 210 are disposed alongside the fin elements 204 and isolate neighboring fin elements 204. The isolation regions 210 may extend in the same direction as the fin elements 204, in some embodiments. In addition, the fins 204 (or fin-shaped active regions) may be described as extending in a direction parallel to the plane defined by section BB′ of FIG. 2A, and the gate structure 208 may be described as extending in a direction parallel to a plane defined by section CC′ of FIG. 2A. Thus, in some examples, the fins 204 and the gate structure 208 may be described as extending in two different directions, where the two different directions are perpendicular to each other, in some embodiments.

FIG. 2B provides a simplified top-down layout view of a planar FET 250, which may be substantially the same as the planar FET 100, discussed above. The planar FET 250 may include an active region 252 within which source/drain regions 254, 256 are defined. The planar FET 250 further includes a gate stack 258 extending over the active region 252, and where the source/drain regions 254, 256 are defined on either side of the gate stack 258. In various embodiments, the gate stack 258 may be substantially the same as the gate 104 and the source/drain regions 254, 256 may be substantially the same as the source/drain regions 110, 112, each of which has been discussed above with reference to the planar FET 100 of FIG. 1A. A channel region of the planar FET 250 is defined between the source/drain regions 254, 256 under the gate stack 258, and within an underlying substrate. The planar FET 250 also includes isolation regions 260, which are disposed alongside the active region 252 and which serves to isolate neighboring active regions. In some cases, the isolation regions 260 may include STI features. In addition, the active region 252 may be described as extending in a direction parallel to the plane defined by section DD′ of FIG. 2B, and the gate stack 258 may be described as extending in a direction parallel to a plane defined by section EE′ of FIG. 2B. Thus, in some examples, the active region 252 and the gate stack 258 may be described as extending in two different directions, where the two different directions are perpendicular to each other, in some embodiments. As described in more detail below, in accordance with embodiments of the present disclosure and for a non-planar device and a planar FET formed on a same substrate, the gate of a non-planar device (e.g., such as the non-planar device 200) extends in a first gate direction, and the gate of a planar FET (e.g., such as the planar FET 250) extends in a second gate direction different than the first gate direction. In at least some cases and for first and second non-planar devices formed on a same substrate, the gate of the first non-planar device extends in a first gate direction, and the gate of the second non-planar device extends in a second gate direction different than the first gate direction. In some cases, the first and second gate directions may be perpendicular to each other, while in other cases they are not perpendicular to each other.

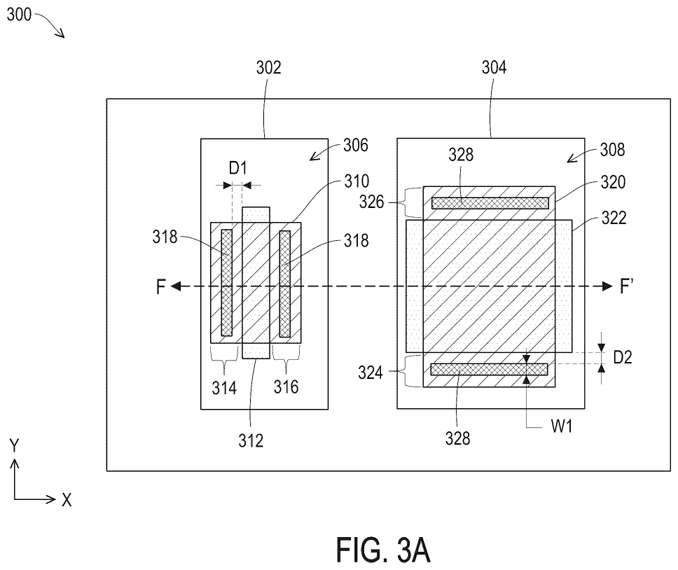

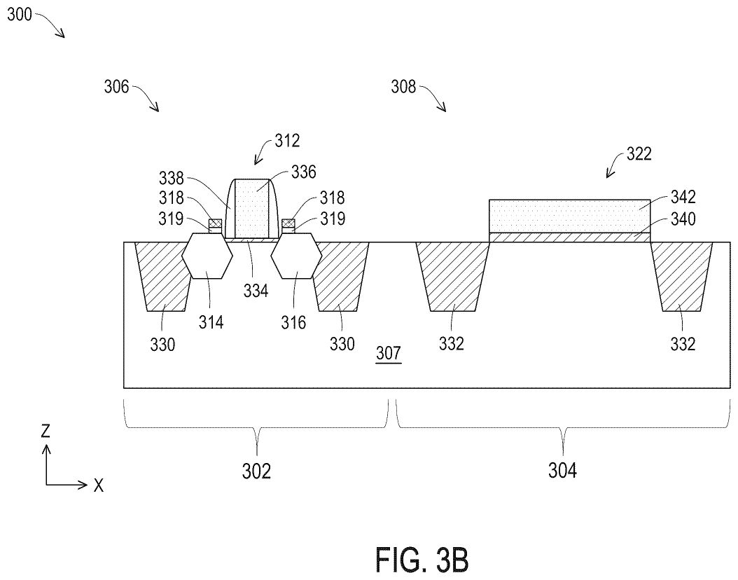

With reference now to FIG. 3A and FIG. 3B, illustrated therein is an embodiment of a multi-voltage IC device 300. Specifically, FIG. 3A provides a top-down view of the multi-voltage IC device 300 along an X-Y plane, and FIG. 3B provides a cross-section view of the multi-voltage IC device 300 along an X-Z plane that is substantially parallel to a plane defined by section FF′ of FIG. 3A. In the illustrated example, the multi-voltage IC device 300 includes a non-planar device region 302 and a MV/HV transistor region 304 (which may also be referred to as a planar device region 304). In some embodiments, the non-planar device region 302 may include a non-planar device 306, or more generally, one or more non-planar devices such as the non-planar devices 150, 200 (e.g., FinFETs and/or GAA transistors), and which may include low-voltage (LV) transistors used to implement core/logic devices, memory devices (e.g., such as SRAM transistors), or other devices that operate using a substantially nominal voltage. Thus, in some cases, the non-planar device region 302 may be equivalently referred to as a LV transistor region. In some examples, the MV/HV transistor region 304 may include a planar FET 308, or more generally, one or more planar FETs such as the planar FETs 100, 250, and which include MV and/or HV transistors used to implement a source driver, a gate driver, or other devices that operate using a higher voltage than the non-planar devices (LV transistors). In some embodiments, one or more devices from the non-planar device region 302 and the MV/HV transistor region 304 may be used to collectively provide various types of IC devices, such as DDIC devices, in some cases. Also, it will be understood that the non-planar device region 302 and the MV/HV transistor region 304 need not be aligned adjacent to each other as shown, but rather the illustrated embodiment is provided for clarity of discussion.

For clarity of discussion, and in the example of FIG. 3A, the non-planar device 306 of the non-planar device region 302 is illustrated using a simplified layout view that is similar to a portion 235 of the layout view of the non-planar device 200 of FIG. 2A, and the planar FET 308 of the MV/HV transistor region 304 is illustrated using a simplified layout view that is similar to the layout view of the planar FET 250 of FIG. 2B. While illustrated as including one device in each of the non-planar device region 302 and the MV/HV transistor region 304, it will be understood that this is merely exemplary, and more devices may be provided in one or both of the non-planar device region 302 and the MV/HV transistor region 304, in various embodiments.

As shown, the non-planar device 306 includes an active region 310, which in some embodiments may be similar to the fin-shaped active regions provided by the fins 204, as discussed above. Thus, in some examples, the active region 310 may be described as extending in an X-direction. The non-planar device 306 further includes a gate structure 312, which may be similar to the gate structures 208, 158 discussed above. The gate structure 312, as shown, extends in a Y-direction. For purposes of this disclosure, and in some embodiments, the Y-direction may be equivalently referred to as a first gate direction, where the first gate direction is associated with the non-planar device 306 or more generally with the non-planar device region 302. As further shown, the non-planar device 306 may include a source region 314 and a drain region 316 disposed on either side of the gate structure 312. In some embodiments, the source/drain regions 314, 316 may be similar to the source/drain regions 205, 207, described above. In some examples, the non-planar device 306 also includes source/drain contact layers 318 extending in the Y-direction, where the source/drain contact layers 318 include a conductive layer that is electrically coupled to the underlying source/drain regions 314, 316 by way of a silicide layer 319, where an electrical conductivity of the silicide layer 319 is greater than an electrical conductivity of the source/drain regions 314, 316, and where an electrical conductivity of the source/drain contact layers 318 is greater than the electrical conductivity of the silicide layer 319 and the source/drain regions 314, 316.

The planar FET 308 includes an active region 320, which in some cases may be similar to the active region 252, described above. In the illustrated example, the active region 320 may be described as extending in the Y-direction. The planar FET 308 further includes a gate stack 322, which may be similar to the gate stacks 258, 104, discussed above. The gate stack 322, as shown, extends in an X-direction. For purposes of this disclosure, and in some embodiments, the X-direction may be equivalently referred to as a second gate direction, where the second gate direction is associated with the planar FET 308 or more generally with the MV/HV transistor region 304. In some embodiments, the second gate direction is different than the first gate direction. In some cases, the first and second gate directions may be perpendicular to each other, while in other cases they are not perpendicular to each other. As further shown, the planar FET 308 may include a source region 324 and a drain region 326 disposed on either side of the gate stack 322. In some embodiments, the source/drain regions 324, 326 may be similar to the source/drain regions 254, 256, described above. In some examples, the planar FET 308 includes source/drain contact layers 328 extending in the X-direction, where the source/drain contact layers 328 include a conductive layer that is electrically coupled to the underlying source/drain regions 324, 326 by way of a silicide layer 329, where an electrical conductivity of the silicide layer 329 is greater than an electrical conductivity of the source/drain regions 324, 326, and where an electrical conductivity of the source/drain contact layers 328 is greater than the electrical conductivity of the silicide layer 329 and the source/drain regions 324, 326.

Still referring to the example of FIG. 3A, a distance D1 may be defined for the non-planar device 306 as a distance between the gate structure 312 and an adjacent source/drain contact layer 318. Thus, the distance D1 may be equivalently referred to as a first gate-to-source/drain contact distance. Similarly, a distance D2 may be defined for the planar FET 308 as a distance between the gate stack 322 and an adjacent source/drain contact layer 328. Thus, the distance D2 may be equivalently referred to as a second gate-to-source/drain contact distance. Due to the orientation of the non-planar device 306 (with a gate that extends in the first gate direction) and the planar FET 308 (with a gate that extends in the second gate direction), the distance D1 may be defined in the X-direction, and the distance D2 may be defined in the Y-direction. More generally, the distance D1 and the distance D2 may be defined in different directions. In some embodiments, the distance D2 is greater than the distance D1. For example, in some cases, the distance D1 may be in a range of about 7-27 nm, and the distance D2 may be in a range of about 62-82 nm. As merely one example, the distance D1 may be equal to about 17 nm, and the distance D2 may be equal to about 72 nm. In some alternative embodiments, the distance D1 may be less than or equal to the distance D2. It is noted that in some embodiments, and due to the high exposure resolution in the Y-direction, the distance D2 may be decreased (e.g., as compared to the distance D2 in existing implementations) to save additional substrate area. Moreover, in some cases and again due to the high exposure resolution in the Y-direction, a width W1 of the source/drain contact layers 328 of the planar FET 308 may be increased to provide reduced resistance.

FIG. 3B illustrates the multi-voltage IC device 300 including the non-planar device 306 disposed in the non-planar device region 302 and the planar FET 308 disposed in the MV/HV transistor region 304. In particular, the example of FIG. 3B shows that the non-planar device 306 (and thus the non-planar device region 302) and the planar FET 308 (and thus the MV/HV transistor region 304) are formed on a same substrate 307. In some embodiments, the substrate 307 may be substantially the same as the substrates 102, 152 and may include one or more of the materials used for the substrates 102, 152, as described above. As previously noted, devices formed in each of the non-planar device region 304 and the MV/HV transistor region 304 may be manufactured sequentially or in parallel (at the same time) by using the same or similar processes.

In the illustrated example, the non-planar device 306 may include the gate structure 312 having a gate dielectric 334 and a metal gate electrode 336, sidewall spacers 338, the source region 314, the drain region 316, and the source/drain contact layers 318 that include a conductive layer that provides an electrical connection to respective ones of the source/drain regions 314, 316. In some examples, the gate dielectric 334 may include an interfacial layer (e.g., such as the interfacial layer 160) and a gate dielectric layer (e.g., such as the gate dielectric layer 162) formed over the interfacial layer, similar to the gate structure 158, discussed above. In addition, the metal gate electrode 336 may include a conductive layer such as the metal layer 164, also discussed above with reference to the gate structure 158. The gate structure 312 may be formed over the active region 310, which in some embodiments may be similar to the fin-shaped active regions provided by the fins 204, as discussed above. In some embodiments, the sidewall spacers 338 are formed on sidewalls of the gate structure 312, where the sidewall spacers extend in a same direction as the gate structure 312. The sidewall spacers 338 may include a dielectric material such as silicon oxide, silicon nitride, silicon carbide, silicon oxynitride, or combinations thereof. In some examples, the source/drain regions 314, 316 may be substantially the same as the source/drain regions 155, 157, discussed above. In some embodiments, the non-planar device 306 also includes isolation regions 330, which may be substantially the same as the isolation regions 210, 156 discussed above, and which may include STI features, in some cases. The isolation regions may serve to isolate neighboring active regions (or neighboring fin elements) and may interface the gate structure 312 and the sidewall spacers 338.

The example of FIG. 3B also shows that the planar FET 308 may include the gate structure 322 having a gate dielectric 340 and a metal gate electrode 342. In some examples, the gate dielectric 340 may include an interfacial layer and a gate dielectric layer formed over the interfacial layer, similar to the gate dielectric 106 of the gate stack 104, discussed above. In addition, the metal gate electrode 342 may include a conductive layer similar to that described above with respect to the gate electrode 108 of the gate stack 104. The gate structure 322 may be formed over the active region 320, as discussed above. In some embodiments, the planar FET 308 also includes isolation regions 332, which may be similar to the isolation regions 260 discussed above, and which may include STI features, in some cases. In an example, the isolation regions 332 may include a gate cut region, where for example, a trench is formed through a portion of the gate structure 322 and refilled with a dielectric material. The isolation regions 332 may serve to isolate neighboring active regions and/or neighboring devices. In the example of FIG. 3B, and because the planar FET 308 is rotated with respect to the non-planar device 306 (as shown and discussed with reference to FIG. 3A), other features of the planar FET 308 (e.g., such as the source/drain regions 324, 326 and the source/drain contact layers 328) are not visible.

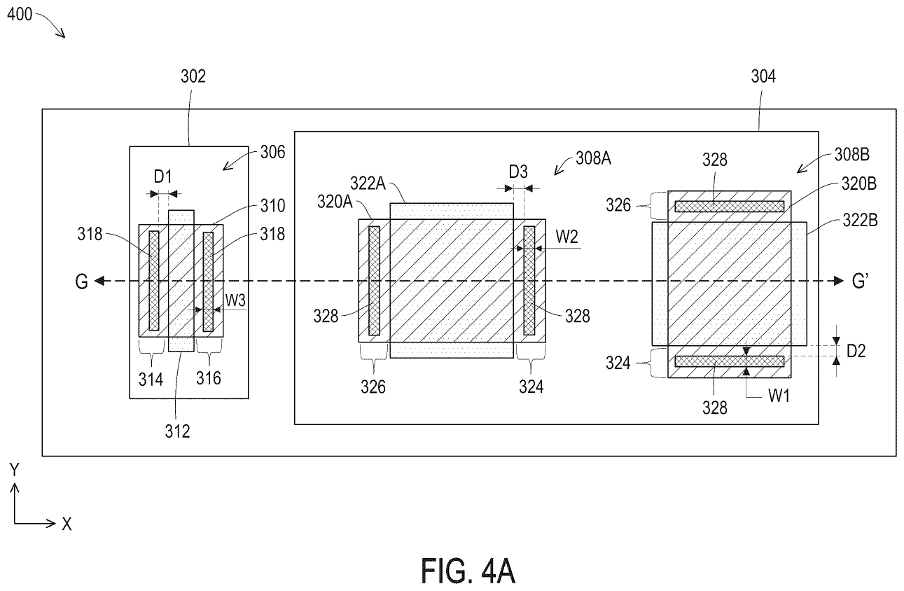

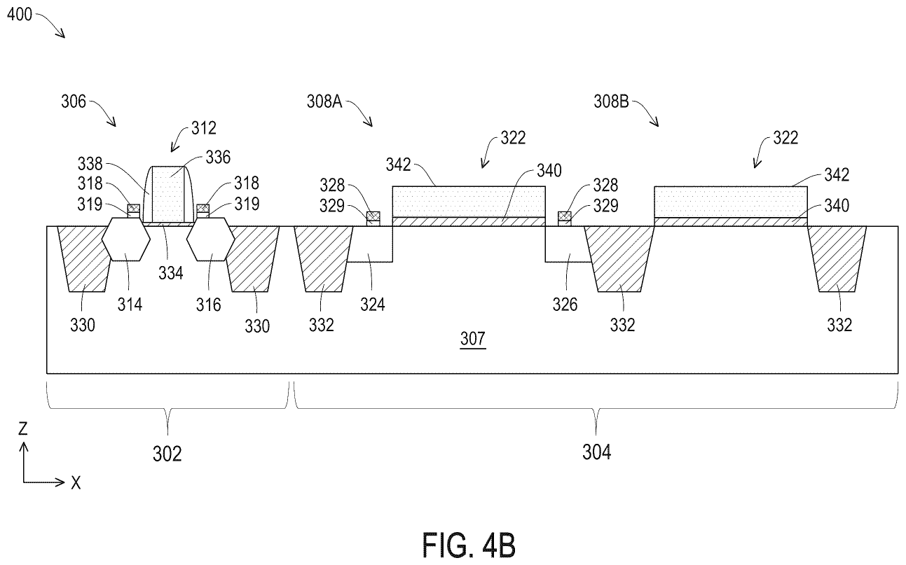

Referring to FIG. 4A and FIG. 4B, illustrated therein is an embodiment of a multi-voltage IC device 400. The multi-voltage IC device 400 is similar in many respects to the multi-voltage IC device 300, described above, and like features are labeled using the same reference numbers. Thus, for clarity of discussion, the discussion of FIGS. 4A and 4B will focus on the differences provided by the multi-voltage IC device 400. FIG. 4A provides a top-down view of the multi-voltage IC device 400 along an X-Y plane, and FIG. 4B provides a cross-section view of the multi-voltage IC device 400 along an X-Z plane that is substantially parallel to a plane defined by section GG′ of FIG. 4A. Like the multi-voltage IC device 300, the multi-voltage IC device 400 includes the non-planar device region 302 and the MV/HV transistor region 304. As described above, the non-planar device region 302 may include the non-planar device 306 or other non-planar devices that operate using a substantially nominal voltage. In some examples, and in contrast to the multi-voltage IC device 300, the MV/HV transistor region 304 of the multi-voltage IC device 400 may include a planar FET 308A and a planar FET 308B, as well as other devices that operate using a higher voltage than the non-planar devices (LV transistors). In some cases, the planar FET 308B may be substantially the same as the planar FET 308, described above. The planar FET 308A may also be substantially the same as the planar FET 308, except that the planar FET 308A has an orientation that is rotated with respect to the planar FET 308B. In the present example, the planar FETs 308A, 308B are illustrated as being disposed in the same MV/HV transistor region 304, but it will be understood that in some embodiments, each of the planar FET 308A and the planar FET 308B may be disposed in different MV/HV transistor regions. It is again noted that the non-planar device region 302 and the MV/HV transistor region 304 need not be aligned adjacent to each other as shown, but rather the illustrated embodiment is provided for clarity of discussion.

As noted above, the non-planar device region 302 may include the non-planar device 306, which has been described above with reference to the multi-voltage IC device 300. In particular, non-planar device 306 includes the active region 310 extending in the X-direction and the gate structure 312 extending in the Y-direction (the first gate direction). The non-planar device 306 also includes the source/drain regions 314, 316 and the source/drain contact layers 318 extending in the Y-direction, as described above.

The planar FET 308A includes an active region 320A, similar to the active region 320, but extending in the X-direction. The planar FET 308B includes an active region 320B, which is substantially the same as the active region 320. The planar FET 308A further includes a gate stack 322A, similar to the gate stack 322, but extending in the Y-direction (the first gate direction). The planar FET 308B further includes a gate stack 322B, which is substantially the same as the gate stack 322, and which extends in the X-direction (the second gate direction). As noted above, the second gate direction is different than the first gate direction. In some cases, the first and second gate directions may be perpendicular to each other, while in other cases they are not perpendicular to each other. As further shown, the planar FETs 308A, 308B also include the source/drain regions 324, 326, as well as source/drain contact layers 328, such as described above. In addition, the source/drain contact layers 328 extend in the Y-direction for the planar FET 308A, and the source/drain contact layers 328 extend in the X-direction for the planar FET 308B. The multi-voltage IC device 400 thus shows an example where at least one planar FET (the planar FET 308B, in the present case) of the MV/HV transistor region 304 has a gate that extends in a different direction (X-direction) as compared to the gate of the non-planar device 306 (which extends in the Y-direction). The illustrated example also shows a case where at least one planar FET (the planar FET 308A, in the present case) of the MV/HV transistor region 304 has a gate that extends in a same direction (Y-direction) as the gate of the non-planar device 306 (which also extends in the Y-direction).

Still referring to the example of FIG. 4A, the distance D1 (first gate-to-source/drain contact distance) is defined for the non-planar device 306, and the distance D2 (second gate-to-source/drain contact distance) is defined for the planar FET 308B. In addition, a distance D3 (third gate-to-source/drain contact distance) may be defined for the planar FET 308A. Due to the orientation of the non-planar device 306 (with a gate that extends in the first gate direction), the planar FET 308A (with a gate that extends in the first gate direction), and the planar FET 308B (with a gate that extends in the second gate direction), the distances D1 and D3 may be defined in the X-direction, and the distance D2 may be defined in the Y-direction. More generally, the distances D1 and D3 may be defined in the same direction, while also being defined in a different direction that the distance D2. As noted above, and in some embodiments, the distance D2 is greater than the distance D1. In addition, in some cases, the distance D3 is greater than the distance D1. However, it is also noted that due to the high exposure resolution in the Y-direction, the distance D2 may be less than the distance D3. Moreover, in some embodiments and again due to the high exposure resolution in the Y-direction, the width W1 of the source/drain contact layers 328 of the planar FET 308B may be greater than a width W2 of the source/drain contact layers 328 of the planar FET 308A and greater than a width W3 of the source/drain contact layers 318 of the non-planar device 306.

FIG. 4B illustrates the multi-voltage IC device 400 including the non-planar device 306 disposed in the non-planar device region 302 of the substrate 307 and the planar FETs 308A, 308B disposed in the MV/HV transistor region 304 of the substrate 307. In the illustrated example, the non-planar device 306 may include the gate structure 312, the sidewall spacers 338, the source/drain regions 314, 316, the source/drain contact layers 318, and the isolation regions 330, as previously described. In addition, the planar FET 308B may include the gate structure 322 and the isolation regions 332 on either side of the planar FET 308B. Further, in the example, shown, the planar FET 308A may similarly include the gate structure 322 having the gate dielectric 340 and the metal gate electrode 342. The planar FET 308A may also include the source/drain regions 324, 326 and the source/drain contact layers 328, as previously described. In some embodiments, the isolation regions 332 may also be provided on either side of the planar FET 308A. In the example of FIG. 4B, and because the planar FET 308B is rotated with respect to both the non-planar device 306 and the planar FET 308A (as shown and discussed with reference to FIG. 4A), some features of the planar FET 308B (e.g., such as the source/drain regions 324, 326 and the source/drain contact layers 328) are not visible.

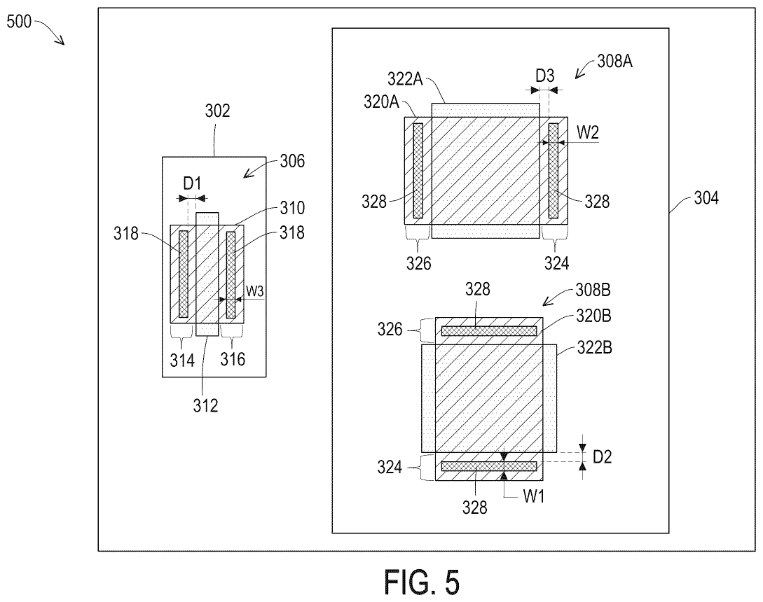

As previously noted, the non-planar device region 302 and the MV/HV transistor region 304 need not be aligned adjacent to each other, nor do devices formed within respective ones of the non-planar device region 302 and the MV/HV transistor region 304 need to be aligned adjacent to each other, such as shown in the examples of FIG. 3A and FIG. 4A. With that in mind, and merely as one illustrative example, FIG. 5 provides a top-down view of a multi-voltage IC device 500 along the X-Y plane. The example of FIG. 5 is similar to the example shown and discussed above with reference to FIG. 4A, except that in the multi-voltage IC device 500, the positions of the planar FETs 308A, 308B within the MV/HV transistor region 304 have been modified. For instance, in the example of FIG. 4A, the planar FETs 308A, 308B are shown as being positioned substantially adjacent to each other along the X-direction. In contrast, in the example of FIG. 5, the planar FETs 308A, 308B are shown as being positioned substantially adjacent to each other along the Y-direction. In some cases, and due to the repositioning of the planar FETs 308A, 308B, the non-planar device 306 may also not be directly adjacent (along the X-direction) to one or both of the planar FETs 308A, 308B.

Generally, positioning and orientation of non-planar devices within the non-planar device region 302, as well as positioning and orientation of planar FETs within the MV/HV transistor region 304, may be modified as needed in accordance with various design and/or performance requirements, such as to reduce/optimize interconnect routing and enhance performance of the multi-voltage IC device, while also adhering to any defined design rules. For example, in some embodiments, a design rule may be defined which specifies that a gate of a non-planar device in the non-planar device region 302 and a gate of a planar FET in the MV/HV transistor region 304 extend in different directions (e.g., such as the first gate direction and the second gate direction, discussed above). In another example, a design rule may be defined which specifies that a gate of a first non-planar device in the non-planar device region 302 and a gate of a second non-planar device in the non-planar device region 302 extend in different directions (e.g., such as the first gate direction and the second gate direction, discussed above). Further, in some examples, a layout design may be modified (e.g., in accordance with one or more design rules) during a design procedure performed by a design house to generate a target layout design of a multi-voltage IC device. The design procedure may include logic design, physical design, and/or place and route, in various examples.

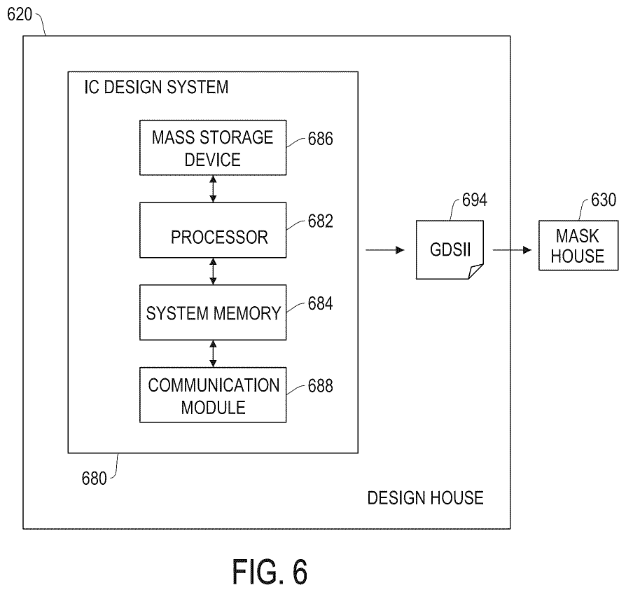

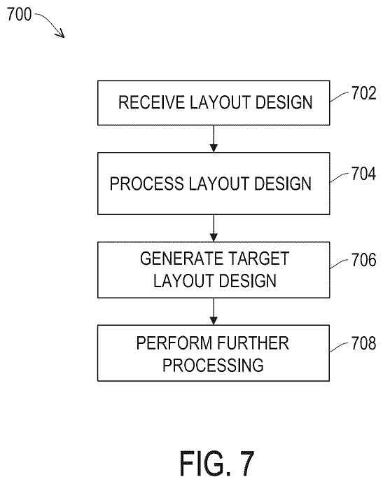

Elaborating on the above, reference is made to FIG. 6, which illustrates an exemplary design house 620. As shown, the design house 620 includes an IC design system 680 that is operable to perform the design procedure such as and including the procedure described below in association with method 700 of FIG. 7. The IC design system 680 is an information handling system such as a computer, server, workstation, or other suitable device. The system 680 includes a processor 682 that is communicatively coupled to a system memory 684, a mass storage device 686, and a communication module 688. The system memory 684 provides the processor 682 with non-transitory, computer-readable storage to facilitate execution of computer instructions by the processor 682. Examples of system memory may include random access memory (RAM) devices such as dynamic RAM (DRAM), synchronous DRAM (SDRAM), solid state memory devices, and/or a variety of other memory devices known in the art. Computer programs, instructions, and data are stored within the mass storage device 686. Examples of mass storage devices may include hard discs, optical disks, magneto-optical discs, solid-state storage devices, and/or a variety other mass storage devices known in the art. The communication module 688 is operable to communicate information such as IC design layout files with the other components of an IC manufacturing system, such as a mask house 130, which uses layout design of a multi-voltage IC device generated by the design house 620 to manufacture one or more photomasks (masks). Examples of communication modules may include Ethernet cards, 802.11 WiFi devices, cellular data radios, and/or other suitable devices known in the art.

In operation, the IC design system 680 is configured to provide an IC design layout including a multi-voltage IC device having optimized interconnect routing and in which a gate of a non-planar device (in a non-planar device region) and a gate of a planar FET (in a MV/HV transistor region) extend in different directions. In at least some cases, the IC design system 680 may also be configured to provide an IC design layout including a multi-voltage IC device having optimized interconnect routing and in which a gate of a first non-planar device (in a non-planar device region) and a gate of a second non-planar device (in the non-planar device region) extend in different directions. In some embodiments, the IC design system 680 provides the IC design layout, which may be in the form of a GDSII file 694, to a mask house 630. As such, the mask house 630 may use the provided IC design layout to manufacture one or more masks, which include the multi-voltage IC device. In alternative embodiments, the IC design layout may be transmitted between components of an IC manufacturing system in alternate file formats such as DFII, CIF, OASIS, or any other suitable file type. Further, the IC design system 680, the IC design house 620, and the mask house 630 may include additional and/or different components in alternative embodiments. In addition, and in some cases, the design house 120, the mask house 130, and an IC manufacturer (e.g., a fab) may have a common owner, and may even coexist in a common facility and use common resources. In various examples, the IC manufacturer uses the mask (or masks) fabricated by the mask house 130 to fabricate the multi-voltage IC device on a semiconductor wafer.

Referring now to FIG. 7, illustrated is a method 700 for generating a layout design for a multi-voltage IC device, in accordance with embodiments of the present disclosure. In some embodiments, the method 700 may be performed by the IC design system 680 of the design house 620. Additional operations can be provided before, during, and after the method 700, and some operations described can be replaced, eliminated, or moved around for additional embodiments of the method. It is also noted that the method 700 is exemplary, and is not intended to limit the present disclosure beyond what is explicitly recited in the claims that follow. It is also noted that certain aspects of the method 700 may include portions of a generalized physical design flow and/or ASIC design flow.

The method 700 begins at block 702 where a layout design for a multi-voltage IC device is received (e.g., by the IC design system 680). In some examples, the layout design may be entered by way of a hardware description language (e.g., VHDL, Verilog, and/or SystemVerilog). The design entered using the hardware description language may be referred to as register transfer level (RTL) design. In some cases, functional/logical verification may be performed after the RTL design.

The method 700 then proceeds to block 704 where the received layout design is processed. In some examples, the processing of block 704 may include performing synthesis to generate a netlist (e.g., a gate-level netlist). In some examples, the processing of block 704 may further include performing partitioning, for example, to separate various functional blocks. In some cases, the processing of block 704 further includes performing floorplanning. By way of example, floorplanning is the process of identifying structures that should be placed close together, and allocating space for them in such a manner as to meet the sometimes conflicting goals of available space, required performance, and the desire to have various structures close to one another. In some embodiments, the processing of block 704 further includes performing placement, which is used to assign locations to various circuit components on a chip. In various examples, the placement process may aim to optimize a total wirelength, timing, congestion, power, as well as to accomplish other objectives. In some examples, the processing of block 704 further includes performing routing, which is used to add wiring (e.g., electrical connections) between the previously placed components while satisfying IC design rules. As merely one example, such design rules may include a design rule which specifies that a gate of a non-planar device in the non-planar device region 302 and a gate of a planar FET in the MV/HV transistor region 304 extend in different directions. In another example, such design rules may include a design rule which specifies that a gate of a first non-planar device in the non-planar device region 302 and a gate of a second non-planar device in the non-planar device region 304 extend in different directions. In still other embodiments, the processing of block 704 may also include clock-tree synthesis, physical verification, timing analysis, GDSII generation, or other suitable processes.

In accordance with embodiments of the present disclosure, layout designs of the non-planar device region 302 and the MV/HV transistor region 304, including positions and orientations of devices in each of the non-planar device region 302 and the MV/HV transistor region 304, are identified and modified as needed (e.g., by the IC design system 680), for example, to reduce/optimize interconnect routing while also adhering to any defined design rules, such as described above. In at least some embodiments, a planar FET of the MV/HV transistor region 304 is identified as having a gate that extends in a same direction as a gate of a non-planar device of the non-planar device region 302. In some embodiments, the IC design system 680 may then rotate the planar FET of the MV/HV transistor region 304 so that respective gates of the planar FET and the non-planar device extend in different directions (e.g., such as the first gate direction and the second gate direction, discussed above). In some embodiments, the IC design system 680 may rotate one or more planar FETs of the MV/HV transistor region 304. In addition, for the rotated planar FETs, the IC design system 680 may also modify (e.g., reduce) a gate-to-source/drain contact distance and/or modify (e.g., increase) a width of a source/drain contact. In addition, and in some embodiments, a position of a planar FET of the MV/HV transistor region 304 may be modified with respect to other planar FETs of the MV/HV transistor region 304 and/or with respect to a non-planar device of the non-planar device region 302. In at least some cases, a first non-planar device of the non-planar device region 302 is identified as having a gate that extends in a same direction as a gate of a second non-planar device of the non-planar device region 302. In some embodiments, the IC design system 680 may then rotate the first or second non-planar device of the non-planar device region 302 so that respective gates of the first and second non-planar devices extend in different directions (e.g., such as the first gate direction and the second gate direction, discussed above). In various examples, modification of the positions and/or orientations of devices in the non-planar device region 302 and/or in the MV/HV transistor region 304 may be performed before, after, or during any of the processing steps of block 704. As merely some examples, such modifications may be performed as part of the floorplanning step, after the floorplanning step and before the placement step, as part of the placement step, after the placement step and before the routing step, or as part of the routing step.

The method 700 then proceeds to block 706 where a target layout design is generated. For example, in some embodiments, the layout design generated by the processing of block 704 may undergo additional processing before a final, target layout design is provided. In some embodiments, such processing may include physical verification and layout post processing. Thereafter, the target layout design may be generated and provided, for example, to a mask house for the manufacture of one or more masks, which include the multi-voltage IC device. The generated target layout design, as previously described and in accordance with embodiments of the present disclosure, may include an IC design layout that includes a multi-voltage IC device having optimized interconnect routing and in which a gate of a non-planar device (in a non-planar device region) and a gate of a planar FET (in a MV/HV transistor region) extend in different directions. In some cases, the generated target layout design may include an IC design layout that includes a multi-voltage IC device having optimized interconnect routing and in which a gate of a first non-planar device (in a non-planar device region) and a gate of a second non-planar device (in the non-planar device region) extend in different directions.

The method 700 then proceeds to block 708 where further processing is performed. By way of example, and in some embodiments, the further processing may include the manufacture of the one or more masks, which include the multi-voltage IC device, using the generated target layout. In some embodiments, the further processing may additionally include fabricating the multi-voltage IC device on a semiconductor wafer, using the one or more masks. While some examples of further processing steps have been provided, it will be understood that other and/or additional further processing steps may be performed without departing from the scope of the present disclosure.

To provide further details regarding the manufacture of devices in the non-planar device portion and devices in the MV/HV transistor portion, reference is now made to the methods of FIG. 8 and FIG. 14. Referring first to FIG. 8, illustrated therein is an exemplary method 800 for the fabrication of non-planar devices including GAA transistors and FinFETs, such as those described above and which may be formed in the non-planar device region 302. It is understood that the method 800 includes steps having features of a CMOS technology process flow and thus, are only described briefly herein. Additional steps may be performed before, after, and/or during the method 800. Moreover, it is noted that the process steps of method 800, including any descriptions given with reference to the figures are merely exemplary and are not intended to be limiting beyond what is specifically recited in the claims that follow.

The method 800 begins at block 802 where fins and shallow trench isolation (STI) features are formed. Referring to the example of FIGS. 9A and 9B, in an embodiment of block 802, a partially fabricated GAA device 900A (FIG. 9A) and a partially fabricated FinFET device 900B (FIG. 9B) are shown. FIGS. 9A and 9B provide isometric views of the GAA device 900A and the FinFET device 900B, respectively, in accordance with some embodiments. For purposes of this discussion, fabrication processes for each of the GAA device 900A and the FinFET device 900B will be discussed in parallel. However, it will be understood that in various embodiments, one device type or both device types (GAA and/or FinFET devices) may be fabricated on a given substrate. Each of the GAA device 900A and the FinFET device 900B include a substrate 902. In some embodiments, the substrate 902 may be a semiconductor substrate such as a silicon substrate. In various embodiments, the substrate 902 may be substantially the same as the substrates 102, 152, 307 and may include one or more of the materials used for the substrates 102, 152, 307, as described above. In addition, each of the GAA device 900A and the FinFET device 900B may include an N-type device formed in an N-type region of the substrate 902 or a P-type device formed in a P-type region of the substrate 902.

As shown in FIG. 9A, the GAA device 900A includes fins 904 extending from the substrate 902, where the fins 904 include a substrate portion and epitaxial layers 906 of a first composition interposed by epitaxial layers 908 of a second composition disposed over the substrate portion. The first and second composition can be different. In an embodiment, the epitaxial layers 906 are SiGe and the epitaxial layers 908 are silicon (Si). However, other embodiments are possible including those that provide for a first composition and a second composition having different oxidation rates and/or etch selectivity. The epitaxial layers 908 or portions thereof may form a channel region of the GAA device 900A. The epitaxial layers 908 may also be used to form portions of source/drain features of the GAA device 900A.

It is noted that while seven (7) layers of the epitaxial layer 306 and six (6) layers of the epitaxial layer 308 are illustrated in FIG. 9A, this is for illustrative purposes only and not intended to be limiting beyond what is specifically recited in the claims. It can be appreciated that any number of epitaxial layers can be formed; the number of layers depending on the desired number of channel regions for the GAA device 900A. In some embodiments, the number of epitaxial layers 908 is between 4 and 10.

In some embodiments, the epitaxial layer 906 has a thickness range of about 4-8 nanometers (nm). In some embodiments, the epitaxial layers 906 may be substantially uniform in thickness. However, in some cases, a topmost layer of the epitaxial layers 906 may be thicker than the remaining epitaxial layers 906, for example, to mitigate layer loss that may occur to the topmost layer of the epitaxial layers 906 during a subsequent CMP process. In some embodiments, the epitaxial layer 908 has a thickness range of about 5-8 nm. In some embodiments, the epitaxial layers 908 are substantially uniform in thickness. As described in more detail below, the epitaxial layer 908 may serve as channel region(s) for the subsequently formed GAA device 900A and its thickness chosen based on device performance considerations. The epitaxial layer 906 may serve to define a gap distance between adjacent channel region(s) for the subsequently formed multi-gate device and its thickness chosen based on device performance considerations.

By way of example, epitaxial growth of the epitaxial layers 906, 908 may be performed by a molecular beam epitaxy (MBE) process, a metalorganic chemical vapor deposition (MOCVD) process, and/or other suitable epitaxial growth processes. In some embodiments, the epitaxially grown layers such as, the layers 908 include the same material as the substrate 902. In some embodiments, the epitaxially grown layers 906, 908 include a different material than the substrate 902. As stated above, in at least some examples, the epitaxial layer 906 includes an epitaxially grown silicon germanium (SiGe) layer and the epitaxial layer 908 includes an epitaxially grown silicon (Si) layer. Alternatively, in some embodiments, either of the epitaxial layers 906, 908 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the epitaxial layers 906, 908 may be chosen based on providing differing oxidation, etch rates, and/or etch selectivity properties.

As shown in FIG. 9B, the FinFET device 900B includes fins 910 extending from the substrate 902, where the fins 910 include a substrate portion and an epitaxial layer 912 formed over the substrate portion. In some embodiments, the epitaxial layer 912 includes Si or SiGe; however, other embodiments are possible. In embodiments where the epitaxial layer 912 includes SiGe, a percentage of Ge in the SiGe may be between about 0-35%. The epitaxial layer 912 or portions thereof may form a channel region of the FinFET device 900B. The epitaxial layer 912 or portions thereof may also be used to form portions of source/drain features of the FinFET device 900B, as discussed below.

Similar to the epitaxial layers 906, 908, epitaxial growth of the epitaxial layer 912 may be performed by an MBE process, an MOCVD process, and/or other suitable epitaxial growth processes. In some embodiments, the epitaxial layer 912 may include the same material as the substrate 902. In some embodiments, the epitaxial layer 912 may include a different material than the substrate 902. As stated above, in at least some examples, the epitaxial layer 912 includes an epitaxially grown silicon or silicon germanium (SiGe) layer. Alternatively, in some embodiments, the epitaxial layer 912 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof.

In various embodiments, the fins 904, 910 may be fabricated using suitable processes including photolithography and etch processes, and in a manner substantially similar to that described above with reference to the fins 154 of the non-planar device 150. Upon formation of the fins 904, 910, trenches may be formed adjacent to and interposing the fins 904, 910. In various embodiments, the trenches may be filled with a dielectric material, which may then be planarized and recessed, to form shallow trench isolation (STI) features 914. In some embodiments, the dielectric layer used to fill the trenches may include SiO₂, silicon nitride, silicon oxynitride, fluorine-doped silicate glass (FSG), a low-k dielectric, combinations thereof, and/or other suitable materials known in the art. In various examples, the dielectric layer may be deposited by a CVD process, a subatmospheric CVD (SACVD) process, a flowable CVD process, an ALD process, a PVD process, and/or other suitable process. In some embodiments, the devices 900A, 900B may be annealed, for example, to improve the quality of the dielectric layer. In some embodiments, the dielectric layer (and thus the STI features 914) may include a multi-layer structure, for example, having one or more liner layers.

As shown in the example of FIGS. 9A and 9B, the STI features 914 are recessed such that the fins 904, 910 extend above the STI features 914. In some embodiments, the recessing process may include a dry etching process, a wet etching process, and/or a combination thereof. In some embodiments, a recessing depth is controlled (e.g., by controlling an etching time) so as to result in a desired height of the exposed upper portion of the fin elements 904, 910. In some embodiments, the height exposes each of the epitaxial layers 906, 908 of the GAA device 900A, and substantially all of the epitaxial layer 912 of the FinFET device 900B.

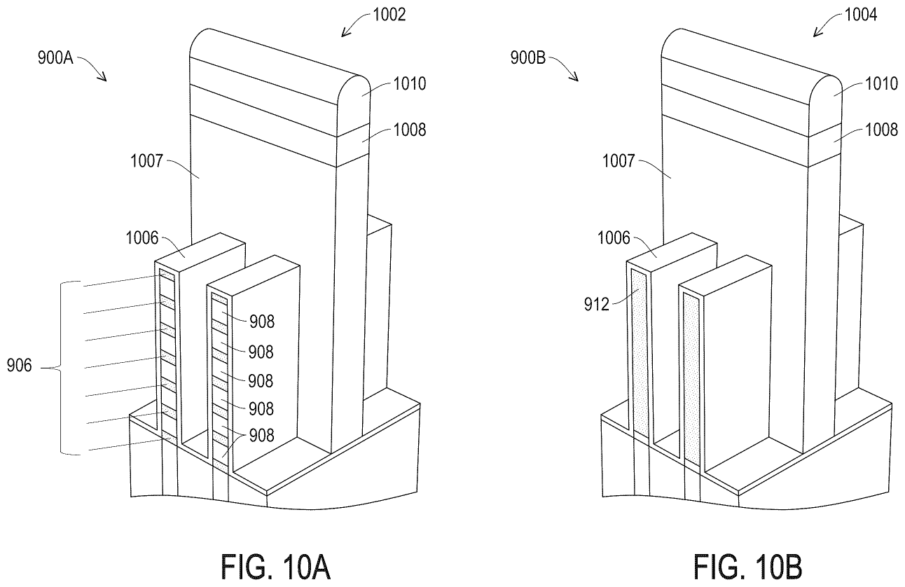

The method 800 then proceeds to block 804 where a dummy gate structure is formed. While the present discussion is directed to a replacement gate (gate-last) process whereby a dummy gate structure is formed and subsequently replaced, other configurations (e.g., such as gate-first) may be possible. With reference to FIGS. 10A and 10B, in an embodiment of block 804, a gate stack 1002 is formed over the fins 904 of the GAA device 900A, and a gate stack 1004 is formed over the fins 910 of the FinFET device 900B. FIGS. 10A and 10B provide isometric views of the GAA device 900A and the FinFET device 900B, respectively, in accordance with some embodiments. In an embodiment, the gate stacks 1002, 1004 are dummy (sacrificial) gate stacks that are subsequently removed and replaced, as discussed below.

In some embodiments, prior to forming the gate stacks 1002, 1004, a dielectric layer 1006 may be optionally formed. In some embodiments, the dielectric layer 1006 is deposited over the substrate 902 and over the fins 904, 910, including within trenches between adjacent fins 904, 910. In some embodiments, the dielectric layer 1006 may include SiO₂, silicon nitride, a high-K dielectric material or other suitable material. In various examples, the dielectric layer 1006 may be deposited by a CVD process, a subatmospheric CVD (SACVD) process, a flowable CVD process, an ALD process, a PVD process, or other suitable process. By way of example, the dielectric layer 1006 may be used to prevent damage to the fin elements 904, 910 by subsequent processing (e.g., subsequent formation of the dummy gate).

In some embodiments using a gate-last process, the gate stacks 1002, 1004 are dummy gate stacks and will be replaced by the final gate stack at a subsequent processing stage of the GAA device 900A and the FinFET device 900B. In particular, the gate stacks 1002, 1004 may be replaced at a later processing stage by a high-K dielectric layer (HK) and metal gate electrode (MG). In some embodiments, the gate stacks 1002, 1004 are formed over the substrate 902 and are at least partially disposed over the fin elements 904, 910. Additionally, in various embodiments, the gate stacks 1002, 1004 may be formed over the dielectric layer 1006, which was optionally deposited as described above prior to formation of the gate stacks 1002, 1004. The portion of the fin elements 904, 910 underlying the gate stacks 1002, 1004 may be referred to as the channel region. The gate stacks 1002, 1004 may also define a source/drain region of the fins 904, 910, for example, the regions of the fins 904, 910 adjacent to and on opposing sides of the channel region.

In some embodiments, the gate stacks 1002, 1004 include a dielectric layer and an electrode layer disposed over the dielectric layer, where both the dielectric layer and the electrode layer are represented by element 1007. The gate stacks 1002, 1004 may also include one or more hard mask layers 1008, 1010. In some embodiments, the hard mask layer 1008 may include an oxide layer, and the hard mask layer 1010 may include a nitride layer. In some embodiments, the gate stacks 1002, 1004 are formed by various process steps such as layer deposition, patterning, etching, as well as other suitable processing steps. In some examples, the layer deposition process includes CVD (including both low-pressure CVD and plasma-enhanced CVD), PVD, ALD, thermal oxidation, e-beam evaporation, or other suitable deposition techniques, or a combination thereof. In forming the gate stack for example, the patterning process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods.

In some embodiments, the dielectric layer of the gate stacks 1002, 1004 includes silicon oxide. Alternatively, or additionally, the dielectric layer of the gate stacks 1002, 1004 may include silicon nitride, a high-K dielectric material or other suitable material. In some embodiments, the electrode layer of the gate stacks 1002, 1004 may include polycrystalline silicon (polysilicon). In some embodiments, the oxide of the hard mask layer 1008 includes a pad oxide layer that may include SiO₂. In some embodiments, the nitride of the hard mask layer 1010 includes a pad nitride layer that may include Si₃N₄, silicon oxynitride or silicon carbide.

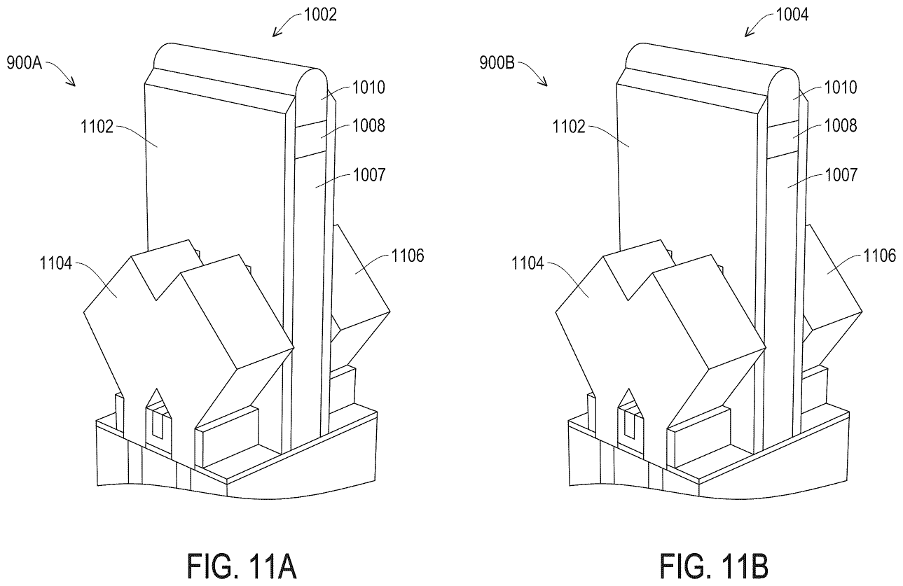

The method 800 then proceeds to block 806 where spacer elements are formed. With reference to FIGS. 11A and 11B, in an embodiment of block 806, sidewall spacers 1102 are formed on the sidewalls of the gate stacks 1002, 1004. FIGS. 11A and 11B provide isometric views of the GAA device 900A and the FinFET device 900B, respectively, in accordance with some embodiments. Formation of the sidewall spacers 1102 may include depositing a spacer material layer over each of the GAA device 900A and the FinFET device 900B. In some examples, the deposited spacer material layer may include a dielectric material such as silicon oxide, silicon nitride, silicon carbide, silicon oxynitride, SiCN films, silicon oxycarbide, SiOCN films, and/or combinations thereof. In some embodiments, the spacer material layer includes multiple layers, such as main spacer walls, liner layers, and the like. By way of example, the spacer material layer may be formed by depositing a dielectric material over the gate stacks 1002, 1004 using processes such as, CVD process, a subatmospheric CVD (SACVD) process, a flowable CVD process, an ALD process, a PVD process, or other suitable process.

In some embodiments, the deposition of the spacer material layer is followed by an etching back (e.g., anisotropically) of the dielectric spacer material. Referring to the example of FIGS. 11A and 11B, after formation of the spacer material layer, the spacer material layer may be etched-back to expose portions of the fin elements 904, 910 adjacent to and not covered by the gate stacks 1002, 1004 (e.g., source/drain regions). The spacer layer material may remain on the sidewalls of the gate stacks 1002, 1004 forming the sidewall spacers 1102. In some embodiments, etching-back of the spacer material layer may include a wet etch process, a dry etch process, a multiple-step etch process, and/or a combination thereof. The spacer material layer may also be removed from a top surface of the gate stacks 1002, 1004, as illustrated in FIGS. 11A and 11B.

The method 800 then proceeds to block 808 where source/drain features are formed. Initially, in an embodiment of block 808, after formation of the gate stacks 1002, 1004 and/or the sidewall spacers 1102, the dielectric layer 1006 (FIG. 10A/10B) may be etched-back (if present) to expose portions of the fins 904, 910 not covered by the gate stacks 1002, 1004 (e.g., for example, in source/drain regions), and including portions of the epitaxial layers 906, 908, and 912. In some examples, the dielectric layer 1006 may be etched-back substantially to the underlying STI 914. In some embodiments, etching-back of the dielectric layer 1006 may include a wet etch process, a dry etch process, a multiple-step etch process, and/or a combination thereof. Thus, in some embodiments, preserving the dielectric layer 1006 during formation of the gate stacks 1002, 1004 serves to effectively protect the fins 904, 910 during such processing.

Referring again to the example of FIGS. 11A and 11B, in a further embodiment of block 808, source/drain features 1104, 1106 are formed in source/drain regions adjacent to and on either side of the gate stacks 1002, 1004. In some embodiments, the source/drain features 1104, 1106 are formed by epitaxially growing a semiconductor material layer on the exposed fins 904, 910 in the source/drain regions. In various embodiments, the semiconductor material layer grown to form the source/drain features 1104, 1106 may include Ge, Si, GaAs, AlGaAs, SiGe, GaAsP, SiP, or other suitable material. The source/drain features 1104, 1106 may be formed by one or more epitaxial (epi) processes. In some embodiments, the source/drain features 1104, 1106 may be in-situ doped during the epi process. For example, in some embodiments, epitaxially grown SiGe source/drain features may be doped with boron. In some cases, epitaxially grown Si epi source/drain features may be doped with carbon to form Si:C source/drain features, phosphorous to form Si:P source/drain features, or both carbon and phosphorous to form SiCP source/drain features. In some embodiments, the source/drain features 1104, 1106 are not in-situ doped, and instead an implantation process is performed to dope the source/drain features 1104, 1106. In some embodiments, formation of the source/drain features 1104, 1106 may be performed in separate processing sequences for each of an N-type source/drain feature (e.g., for an N-type GAA device 900A or an N-type FinFET device 900B) and a P-type source/drain feature (e.g., for a P-type GAA device 900A or a P-type FinFET device 900B).

The method 800 then proceeds to block 810 where an inter-layer dielectric (ILD) layer is formed. Referring to the example of FIGS. 12A, 12B, 12C, and 12D, in an embodiment of block 810, an ILD layer 1202 is formed over each of the GAA device 900A and the FinFET device 900B. FIGS. 12A and 12B provide isometric views of the GAA device 900A and the FinFET device 900B, respectively, in accordance with some embodiments. FIGS. 12C and 12D provide cross-section views of the GAA device 900A and the FinFET device 900B, respectively, along a plane parallel to section X1-X1′, as shown in FIGS. 12A and 12B. In some embodiments, a contact etch stop layer (CESL) is formed over each of the GAA device 900A and the FinFET device 900B prior to forming the ILD layer 1202. In some examples, the CESL includes a silicon nitride layer, silicon oxide layer, a silicon oxynitride layer, and/or other materials known in the art. The CESL may be formed by plasma-enhanced chemical vapor deposition (PECVD) process and/or other suitable deposition or oxidation processes. In some embodiments, the ILD layer 1202 includes materials such as tetraethylorthosilicate (TEOS) oxide, un-doped silicate glass, or doped silicon oxide such as borophosphosilicate glass (BPSG), fluorosilicate glass (FSG), phosphosilicate glass (PSG), boron doped silicon glass (BSG), and/or other suitable dielectric materials. The ILD layer 1202 may be deposited by a PECVD process or other suitable deposition technique. In some embodiments, after formation of the ILD layer 1202, each of the GAA device 900A and the FinFET device 900B may be subject to a high thermal budget process to anneal the ILD layer 1202.

In some examples, after depositing the ILD layer 1202 (and/or CESL or other dielectric layers), a planarization process may be performed to expose a top surface of the gate stacks 1002, 1004 of the GAA device 900A and the FinFET device 900B. For example, a planarization process includes a CMP process which removes portions of the ILD layer 1202 (and CESL layer, if present) overlying the gate stacks 1002, 1004 and planarizes a top surface of each of the GAA device 900A and the FinFET device 900B. In addition, the CMP process may remove the hard mask layers 1008, 1010 overlying the gate stacks 1002, 1004 to expose the underlying electrode layer, such as a polysilicon electrode layer, of the dummy gate.

The method 800 proceeds to block 812 where the dummy gate (see block 804) is removed and a channel layer release process is performed if needed (e.g., as needed for fabrication of the GAA device 900A). Referring to the example of FIGS. 12A, 12B, 12C, 12D, 12E, and 12F, in an embodiment of block 812, the electrode layer and dielectric layer of the dummy gate stacks 1002, 1004 over each of the GAA device 900A and the FinFET device 900B are removed, and a channel layer release process is performed to the GAA device 900A to release the semiconductor channel layers (e.g., the epitaxial layers 908). FIGS. 12E and 12F provide cross-sections views of the GAA device 900A and the FinFET device 900B, respectively, along a plane parallel to sections Y1-Y1′, as shown in FIGS. 12A and 12B.

In some embodiments, an electrode layer (e.g., such as a polysilicon gate electrode) of the dummy gate stacks 1002, 1004 over each of the GAA device 900A and the FinFET device 900B may initially be removed, by suitable etching processes. After removal of the dummy electrode layer, an etching process is performed to etch the dummy dielectric layer of the dummy gate stacks 1002, 1004 over each of the GAA device 900A and the FinFET device 900B. Stated another way, removal of the dummy gate in block 812 may include removal of the element 1007 (which includes the dummy dielectric layer and electrode layer) from the gate stacks 1002, 1004 of each of the GAA device 900A and the FinFET device 900B. In some examples, the etching processes may include a wet etch, a dry etch, or a combination thereof.

After removing the dummy gate from the GAA device 900A and the FinFET device 900B, in some examples and in an embodiment of block 812, a channel release process is performed to the GAA device 900A, where the epitaxial layers 906 (dummy layers) in the channel region of the GAA device 900A may be selectively removed (e.g., using a selective etching process), while the epitaxial layers 908 (semiconductor channel layers) remain substantially unetched. In some embodiments, the selected epitaxial layer(s) are removed from the fins 904 through a trench provided by the removal of the dummy gate of the GAA device 900A. In some embodiments, the selective etching process may include a selective wet etching process. In some cases, the selective wet etching includes ammonia and/or ozone. As merely one example, the selective wet etching process includes tetra-methyl ammonium hydroxide (TMAH). In some embodiments, the selective etching process may include a dry, plasma-free etching process.

It is noted that as a result of the selective removal of the epitaxial layers 906 (dummy layers), gaps 1204 are formed between the adjacent semiconductor channel layers (the epitaxial layers 908) in the channel region of the GAA device 900A, as illustrated in FIGS. 12A, 12C, and 12E. By way of example, the gaps 1204 may serve to expose surfaces of the epitaxial layers 908, upon which one or more layers of a gate structure will be formed. For instance, as described in more detail below, portions of gate structures (e.g., including a metal gate stack having an interfacial layer, a high-K dielectric layer, and one or more metal electrode layers) will be formed within the gaps 1204 between adjacent semiconductor channel layers (the epitaxial layers 908). In some embodiments, after removing the dummy layers (the epitaxial layers 906), and prior to forming the portions of the gate structures, a sheet trim process (e.g., an etching process) may be performed to modify a profile of the semiconductor channel layers (e.g., the epitaxial layers 908) to achieve desired dimensions and/or desired shapes (e.g., cylindrical-shaped (e.g., nanowire), rectangular-shaped (e.g., nanobar), sheet-shaped (e.g., nanosheet), etc.) of the semiconductor channel layers (the epitaxial layers 908). Thus, after block 812, portions of the semiconductor channel layers (the epitaxial layers 908) used to form the channel region of the GAA device 900A, and portions of the epitaxial layer 912 used to form the channel region of FinFET device 900B, are exposed.

The method 800 then proceeds to block 814 where a gate structure is formed for each of the GAA device 900A and the FinFET device 900B. As described in more detail below, the gate structure may include a gate dielectric and a metal gate formed over the gate dielectric. In some embodiments, the gate structure may form the gate associated with the plurality of semiconductor channels (epitaxial layers 908) of the GAA device 300A, as well as the gate associated with the semiconductor channel provided by the epitaxial layer 912 in the channel region of the FinFET device 900B.

Referring to the example of FIGS. 13A, 13C, and 13E, in an embodiment of block 814, a gate dielectric is formed within the trench of the GAA device 900A provided by the removal of the dummy gate and the channel release process, described above with reference to block 812. FIG. 13A provides an isometric view of the GAA device 900A, in accordance with some embodiments. FIG. 13C provides a cross-section view of the GAA device 900A along a plane parallel to section X1-X1′, as shown in FIG. 12A. FIG. 13E provides a cross-section view of the GAA device 900A along a plane parallel to section Y1-Y1′, as shown in FIG. 12A. In various embodiments, the gate dielectric includes an interfacial layer (IL) 1302 and a high-K gate dielectric layer 1304 formed over the interfacial layer. High-K gate dielectrics, as used and described herein, include dielectric materials having a high dielectric constant, for example, greater than that of thermal silicon oxide (~3.9). The gate dielectric, including the IL 1302 and the high-K gate dielectric layer 1304 over the IL 1302, is also formed within the trench of the FinFET device 900B provided by the removal of the dummy gate, as shown in the example of FIGS. 13B, 13D, and 13F. FIG. 13B provides an isometric view of the FinFET device 900B, in accordance with some embodiments. FIG. 13D provides a cross-section view of the FinFET device 900B along a plane parallel to section X1-X1′, as shown in FIG. 12B. FIG. 13F provides a cross-sections view of the FinFET device 900B along a plane parallel to section Y1-Y1′, as shown in FIG. 12B.

In some embodiments, the interfacial layer 1302 may include a dielectric material such as silicon oxide (SiO₂), HfSiO, or silicon oxynitride (SiON). More generally, the interfacial layer 1302 may be substantially the same as the interfacial layer described as part of the gate dielectric 106. The high-K gate dielectric layer 1304 may include a high-K dielectric layer such as hafnium oxide (HfO₂). More generally, the high-K gate dielectric layer 1304 may be substantially the same as the high-K gate dielectric layer described as part of the gate dielectric 106.

In various examples, after deposition of the interfacial layer 1302 and/or after deposition of the high-K gate dielectric layer 1304, a post-deposition anneal (PDA) process may be performed to reduce the interface traps and oxide traps, thereby reducing flicker noise. In some embodiments, the PDA process is performed at a PDA soak temperature of between about 80-150 degrees Celsius in a nitrogen (N₂) ambient for a duration of about 40-80 seconds. The PDA process may have the effect of filling oxide vacancies, thereby reducing oxide trapping centers.

In a further embodiment of block 814, a metal gate including a metal layer 1306 is formed over the gate dielectric of the GAA device 900A and over the gate dielectric of the FinFET device 900B. The metal layer 1306 may include a metal, metal alloy, or metal silicide. Additionally, the formation of the gate dielectric/metal gate stack may include depositions to form various gate materials, one or more liner layers, and one or more CMP processes to remove excessive gate materials and thereby planarize a top surface of the GAA device 900A and the FinFET device 900B. In some examples, after formation of the metal layer 1306, an optional post-metallization anneal (PMA) process may be performed to further reduce the interface traps and oxide traps, thereby reducing flicker noise.

In some embodiments, the metal layer 1306 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. More generally, the metal layer 1306 may be substantially the same as the gate electrode 108 described as part of the gate stack 104. In at least some cases, the metal layer 1306 may include a capping layer (e.g., such as a TiN capping layer) formed over the metal layer 1306. Further, the metal layer 1306 may be formed separately for N-type and P-type transistors which may use different metal layers. In various embodiments, a CMP process may be performed to remove excessive metal from the metal layer 1306, and thereby provide a substantially planar top surface of the metal layer 1306. In addition, the metal layer 1306 may provide an N-type or P-type work function, may serve as a gate electrode of the GAA device 900A and the FinFET device 900B, and in at least some embodiments, the metal layer 1306 may include a polysilicon layer. With respect to the GAA device 900A, the gate structure includes portions that interpose each of the epitaxial layers 908, which each form channels of the GAA device 900A.

It is noted that the GAA device 900A is illustrated as not including an inner spacer layer at lateral ends 1311 of the portions of the gate structure disposed between adjacent epitaxial layers 908 (e.g., as shown in FIG. 13C). However, in some cases, the GAA device 900A may include inner spacers, where the source/drain features 1104, 1106 would be in contact with such inner spacers in addition to contacting the semiconductor channel layers (the epitaxial layers 908). In embodiments that include inner spacers, lateral ends of the dummy layers (the epitaxial layers 906) under the sidewall spacers 1102 may be recessed prior to formation of the source/drain features 1104, 1106, with inner spacers being formed within such recesses. The inner spacers would then remain in place after the channel layer release process (block 812), with the inner spacers subsequently disposed at lateral ends 1311 of the portion of the gate structure disposed between adjacent epitaxial layers 908.

For purposes of the present example as shown in FIG. 13C, the spacing between adjacent epitaxial layers 908 includes merged IL/HK layers (e.g., the interfacial layer 1102 and the high-K gate dielectric layer 1104), without a dedicated inner spacer. As also shown in the example of FIG. 13C, the semiconductor channel layers (the epitaxial layers 908) and the merged IL/HK layers extend beneath the sidewall spacers 1102 while abutting (contacting) the source/drain features 1104, 1106. It is also noted that in some embodiments, the spacing between adjacent nanowires (e.g., between adjacent epitaxial layers 908 in a NW-Y direction, as discussed below) may include merged interfacial layers 1302 without the high-K gate dielectric layer 1304. In such cases, the high-K gate dielectric layer 1304 would still be disposed at least on lateral sides (e.g., in a NW-X direction, discussed below) of the nanowires. Additionally, in some examples, an end of the high-K gate dielectric layer 1304, or an end of the interfacial layer 1302, may be substantially aligned with an outer lateral surface of the sidewall spacers 1102 (e.g., the surface of the sidewall spacers 1102 that abuts the ILD layer 1202), as shown in FIG. 13C.

FIG. 13G provides a zoomed-in cross-section view of a portion of FIG. 13E, which more clearly illustrates the structure and sizes of various aspects of the GAA device 900A. In some embodiments, a nanowire X dimension (NW-X) is equal to about 5-14 nm, and a nanowire Y dimension (NW-Y) is equal to about 5-8 nm. In some cases, the nanowire X dimension (NW-X) is substantially the same as the nanowire Y dimension (NW-Y). By way of example, if the nanowire X dimension (NW-X) is greater than the nanowire Y dimension (NW-Y), then the nanowire structure may instead be referred to as a “nanosheet”. In some cases, a spacing/gap between adjacent nanowires (NW-space) is equal to about 4-8 nm. It is noted that the spacing/gap between adjacent nanowires (NW-space) is substantially equal to the thickness of the epitaxial layer 906, which was previously disposed between adjacent nanowires, and which was removed at block 812, as discussed above. In some cases, the thickness of the epitaxial layer 906, and thus the resulting spacing/gap between adjacent nanowires, may be chosen to provide a desired thickness of the merged interfacial layer or merged interfacial layer/high-K gate dielectric layer between the adjacent nanowires, to provide complete gap fill between adjacent nanowires that also extends beneath the sidewall spacers 1102, and/or to provide a desired number of channel regions for the GAA device 900A (e.g., a smaller spacing between adjacent nanowires may provide for additional epitaxial layers 908, which form the channel regions for the GAA device 900A). In some embodiments, the IL layer 1302 has a thickness of about 0.5-1.5 nm, and the high-K gate dielectric layer 1304 has a thickness of about 1-3 nm.

Each of the GAA device 900A and the FinFET device 900B may undergo further processing to form various features and regions known in the art. For example, subsequent processing may form contact openings, contact metal, as well as various contacts/vias/lines and multilayer interconnect features (e.g., metal layers and interlayer dielectrics) on the substrate 902, configured to connect the various features to form a functional circuit that may include one or more non-planar and planar devices, in accordance with embodiments of the present disclosure. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 800, and some process steps described above may be replaced or eliminated in accordance with various embodiments of the method 800.

Referring now to FIG. 14, illustrated therein is an exemplary method 1400 for the fabrication of planar devices, such as those described above and which may be formed in the MV/HV transistor region 304. The method 1400 is discussed below with reference to FIGS. 15-21, which provide cross-section views of a planar device 1500 at different stages of fabrication, in accordance with some embodiments. It is understood that the method 1400 includes steps having features of a CMOS technology process flow and thus, are only described briefly herein. Additional steps may be performed before, after, and/or during the method 1400. Moreover, it is noted that the process steps of method 1400, including any descriptions given with reference to the figures are merely exemplary and are not intended to be limiting beyond what is specifically recited in the claims that follow.

The method 1400 begins at block 1402 where isolation features are formed. Referring to the example of FIG. 15, in an embodiment of block 1402, an isolation feature 1504 is formed in a substrate to define active regions 1506, 1508. In various embodiments, the active regions 1506, 1508 may include N-type device regions, P-type devices region, or a combination thereof. In some embodiments, the substrate 1502 may be a semiconductor substrate such as a silicon substrate. In various embodiments, the substrate 1502 may be substantially the same as the substrates 102, 152, 307, 902 and may include one or more of the materials used for the substrates 102, 152, 307, 902, as described above. The substrate 1502 may also include various N-well and P-well regions formed in the active regions 1506, 1508. In some cases, the isolation feature 1504 may include an STI feature, similar to the STI features described above. Alternatively, in some cases, the isolation feature may include a local oxidation of silicon (LOCOS) feature.

The method 1400 proceeds to block 1404 where dummy gate structures are formed. With reference to FIGS. 15 and 16, in an embodiment of block 1404, gate stacks 1622 are formed in each of the active regions 1506, 1508 on either side of the isolation feature 1504. The gate stacks may include a gate dielectric layer 1640 and a gate electrode 1642. In some examples, the gate dielectric layer 1640 may include an interfacial layer and a gate dielectric layer formed over the interfacial layer, similar to the gate dielectric 106 of the gate stack 104, discussed above. In addition, the gate electrode 1642 may include polycrystalline silicon (polysilicon). In some cases, one or more hard mask layers (e.g., such as an oxide layer and a nitride layer) may be formed over the gate electrode 1642.. In an embodiment, the gate stacks 1002, 1004 are dummy (sacrificial) gate stacks that are subsequently removed and replaced at a later processing stage by a high-K dielectric layer (HK) and metal gate electrode (MG). The portion of the substrate 1502 underlying the gate stacks 1622 may be referred to as the channel region. The gate stacks 1622 may also define a source/drain region, for example, the regions of the substrate 1502 adjacent to and on opposing sides of the channel region. In some cases, after formation of the gate stacks 1622, the substrate 1502 may be doped (e.g., such as by using an ion implantation process with appropriate dopant species) to form lightly doped drain (LDD) regions and/or pocket implant regions that are self-aligned to the gate stacks 1622.

In some embodiments, the gate stacks 1622 are formed by various process steps such as layer deposition, patterning, etching, as well as other suitable processing steps. In some examples, the layer deposition process includes CVD (including both low-pressure CVD and plasma-enhanced CVD), PVD, ALD, thermal oxidation, e-beam evaporation, or other suitable deposition techniques, or a combination thereof. In forming the gate stack for example, the patterning process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods.

The method 1400 then proceeds to block 1406 where spacer elements are formed. With reference to FIGS. 16 and 17, in an embodiment of block 1406, sidewall spacers 1702 are formed on the sidewalls of the gate stacks 1622. Formation of the sidewall spacers 1702 may include depositing a spacer material layer and etching back (e.g., anisotropically) of the spacer material layer to form the sidewall spacers 1702. In some examples, the deposited spacer material layer may include a dielectric material such as silicon oxide, silicon nitride, silicon carbide, silicon oxynitride, SiCN films, silicon oxycarbide, SiOCN films, and/or combinations thereof. In some embodiments, the spacer material layer includes multiple layers, such as main spacer walls, liner layers, and the like. By way of example, the spacer material layer may be formed by depositing a dielectric material over the gate stacks 1622 using processes such as, CVD process, a subatmospheric CVD (SACVD) process, a flowable CVD process, an ALD process, a PVD process, or other suitable process. In some embodiments, etching-back of the spacer material layer may include a wet etch process, a dry etch process, a multiple-step etch process, and/or a combination thereof. The spacer material layer may also be removed from a top surface of the gate stacks 1622, as illustrated in FIG. 17.

The method 1400 then proceeds to block 1408 where source/drain regions are formed. With reference to FIGS. 17 and 18, in an embodiment of block 1408, source/drain regions 1802 are formed in the substrate 1502 adjacent to the sidewall spacers 1702 and on either side of the gate stacks 1622. In some embodiments, the source/drain regions 1802 are formed by one or more ion implantation processes using appropriate dopant species for N-type and P-type devices. For example, for N-type device regions, the source/drain regions 1802 are doped with P-type dopants, such as boron or BF₂. For the P-type device regions, the source/drain regions 1802 are doped with N-type dopants, such as phosphorous or arsenic. In various embodiments, the source/drain regions 1802 may be formed directly within the substrate 1502, within a P-well structure, within an N-well structure, within a dual-well structure, or using a raised structure. After implantation of the appropriate dopant species, a source/drain activation process may be performed (e.g., such as using a laser annealing process, a rapid thermal annealing process, or a combination thereof). After formation of the source/drain regions 1802, a silicide layer 1804 may be formed over the source/drain regions 1802, where an electrical conductivity of the silicide layer 1804 is greater than an electrical conductivity of the source/drain regions 1802. In various embodiments, the silicide layer 1804 may include nickel silicide (NiSi), titanium silicide (TiSi), cobalt silicide (CoSi), or other appropriate silicide.

The method 1400 then proceeds to block 1410 where an inter-layer dielectric (ILD) layer is formed. With reference to FIGS. 18 and 19, in an embodiment of block 1410, an ILD layer 1902 is formed over the planar device 1500. In some embodiments, a contact etch stop layer (CESL) is formed over the planar device 1500 prior to forming the ILD layer 1902. In some examples, the CESL and the ILD layer 1902 may be substantially the same as described above. In some embodiments, after formation of the ILD layer 1902, the planar device 1500 may be subject to a high thermal budget process to anneal the ILD layer 1902.

In some examples, after depositing the ILD layer 1902 (and/or CESL or other dielectric layers), a planarization process may be performed to expose a top surface of the gate stacks 1622. For example, a planarization process includes a CMP process which removes portions of the ILD layer 1902 (and CESL layer, if present) overlying the gate stacks 1622 and planarizes a top surface of each of the planar device 1500. In addition, the CMP process may remove hard mask layers overlying the gate stacks 1622 to expose the underlying gate electrode 1642, such as a polysilicon electrode layer, of the dummy gates.

The method 1400 proceeds to block 1412 where the dummy gate stacks 1622 are removed. With reference to FIGS. 19 and 20, in an embodiment of block 1412, the gate electrode 1642 and the gate dielectric layer 1640 of the dummy gate stacks 1622 are removed to form trenches 2002. In some embodiments, the gate electrode 1642 (e.g., such as a polysilicon gate electrode) of the dummy gate stacks 1622 may initially be removed, by suitable etching processes. After removal of the dummy gate electrode 1642, an etching process is performed to etch the dummy gate dielectric layer 1640 of the dummy gate stacks 1622. In some examples, the etching processes may include a wet etch, a dry etch, or a combination thereof.

The method 1400 then proceeds to block 1414 where a gate structure is formed. As described in more detail below, the gate structure may include a gate dielectric and a metal gate formed over the gate dielectric. In some embodiments, the gate structure may form the gate associated with N-type and/or P-type transistors formed in each of the active regions 1506, 1508. In some embodiments, a gate dielectric 2102 is initially formed within the trench 2002 provided by the removal of the dummy gate stacks 1622. In accordance with embodiments of the present disclosure, MV/HV transistors may be implemented using planar transistors, such as the planar device 1500. Thus, in various embodiments, the gate dielectric 2102 of the planar device 1500 may be thicker, for example, than the gate dielectric of the GAA device 900A and the FinFET device 900B. Moreover, in some embodiments, the gate dielectric 2102 of HV transistors may be thicker than the gate dielectric 2102 of MV transistors. In some examples, a metal gate electrode 2104 is formed over the gate dielectric 2102 within the trench 2002. In some cases, the formation of the gate dielectric 2102 and the metal gate electrode 2104 may include depositions to form various gate materials, one or more liner layers, and one or more CMP processes to remove excessive gate materials and thereby planarize a top surface of the planar device 1500. In some examples, after formation of the metal gate electrode 2104, an optional PMA process may be performed.

In some embodiments, the gate dielectric 2102 includes an interfacial layer (IL) and a high-K gate dielectric layer formed over the interfacial layer. In some embodiments, the interfacial layer of the gate dielectric 2102 may include a dielectric material such as silicon oxide (SiO₂), HfSiO, or silicon oxynitride (SiON). More generally, the interfacial layer may be substantially the same as the interfacial layer described as part of the gate dielectric 106. The high-K gate dielectric layer of the gate dielectric 2102 may include a high-K dielectric layer such as hafnium oxide (HfO₂). More generally, the high-K gate dielectric layer may be substantially the same as the high-K gate dielectric layer described as part of the gate dielectric 106. In some embodiments, after formation of the gate dielectric 2102, a PDA process may be performed to the planar device 1500.

In some embodiments, the metal gate electrode 2104 may include a metal, metal alloy, or metal silicide. In some cases, the metal gate electrode 2104 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. More generally, the metal gate electrode 2104 may be substantially the same as the gate electrode 108 described as part of the gate stack 104. In at least some cases, the metal gate electrode 2104 may include a capping layer (e.g., such as a TiN capping layer) formed over the metal gate electrode 2104. Further, the metal gate electrode 2104 may be formed separately for N-type and P-type transistors which may use different metal layers. In various embodiments, a CMP process may be performed to remove excessive metal from the metal gate electrode 2104, and thereby provide a substantially planar top surface of the metal gate electrode 2104. In addition, the metal gate electrode 2104 may provide an N-type or P-type work function, may serve as a gate electrode for each of the N-type and/or P-type transistors formed in the active regions 1506, 1508, and in at least some embodiments, the metal gate electrode 2104 may include a polysilicon layer.

The planar device 1500 may undergo further processing to form various features and regions known in the art. For example, subsequent processing may form contact openings, contact metal, as well as various contacts/vias/lines and multilayer interconnect features (e.g., metal layers and interlayer dielectrics) on the substrate 1502, configured to connect the various features to form a functional circuit that may include one or more planar and non-planar devices, in accordance with embodiments of the present disclosure. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 1400, and some process steps described above may be replaced or eliminated in accordance with various embodiments of the method 1400.

Referring now to FIG. 22, illustrated is a method 2200 for fabricating a multi-voltage IC device, in accordance with embodiments of the present disclosure. For example, the method 2200 may be used to fabricate the multi-voltage IC devices 300, 400, 500, previously described. Additional operations can be provided before, during, and after the method 2200, and some operations described can be replaced, eliminated, or moved around for additional embodiments of the method. It is also noted that the method 2200 is exemplary, and is not intended to limit the present disclosure beyond what is explicitly recited in the claims that follow.

The method 2200 begins at block 2202 where a non-planar device portion of a multi-voltage IC device is fabricated on a semiconductor substrate. In some embodiments, fabricating the non-planar device portion may include fabricating one or more non-planar devices (e.g., such as the non-planar devices 150, 200, 306, the GAA device 900A, or the FinFET device 900B) in a non-planar device region (e.g., such as the non-planar device region 302). In some cases, the fabrication of the non-planar device portion may be performed in accordance with the method 800, described above.

After fabricating the non-planar device portion, the method 2200 proceeds to block 2204 where a planar device portion of the multi-voltage IC device is fabricated on the same semiconductor substrate as the non-planar device portion formed at block 2202. In some embodiments, the planar device portion may include an MV/HV transistor portion of the multi-voltage IC device. In some examples, fabricating the planar device portion may include fabricating one or more planar device (e.g., such as the planar devices 100, 250, 308, 308A, 308B) in a planar device region (e.g., such as the planar device region 304, also referred to as the MV/HV transistor region 304). In some cases, the fabrication of the planar device portion may be performed in accordance with the method 1400, described above.

While the method 2200 describes the fabrication of the non-planar device portion and the planar device portion as being performed sequentially, in at least some cases, the fabrication of the non-planar device portion and the planar device portion may be performed in parallel (at the same time). Additionally, in various examples, fabrication of the non-planar device portion and the planar device portion may be performed by using the same or similar processes. It is also noted that since the blocks 2202 and 2204 relate to front-end-of-line (FEOL) manufacturing processes (e.g., manufacture of non-planar and planar transistors), the method 2200 may be described as sequentially performing FEOL portions of the manufacturing process for each of the non-planar device portion and the planar device portion.

After fabricating the planar device portion, the method 2200 proceeds to block 2206 where middle-end-of-line (MEOL) and/or back-end-of-line (BEOL) manufacturing processes are performed in parallel (at the same time or simultaneously) for the non-planar device portion and the planar device portion. In some embodiments, the MEOL and BEOL manufacturing processes may include formation of contacts and multilayer interconnect features, among others. Thus, after block 2206, electrical interconnections made be defined between respective non-planar devices, planar devices, and/or other devices (e.g., such as other active and/or passive devices) formed on the same semiconductor substrate.

The various embodiments described herein offer several advantages over the existing art. It will be understood that not all advantages have been necessarily discussed herein, no particular advantage is required for all embodiments, and other embodiments may offer different advantages. For example, embodiments discussed herein include multi-voltage IC devices where an orientation of the MV/HV transistor portion of the multi-voltage IC device may be rotated with respect to the non-planar device portion of the multi-voltage IC device. As a result, and in various embodiments, the gate of a non-planar device of the non-planar device portion may be oriented in a first direction, and the gate of a planar FET of the MV/HV transistor portion may be oriented in a second direction different than the first direction. In some cases, the first direction is perpendicular to the second direction. In addition, and in some embodiments, a first gate-to-source/drain contact distance is defined for the non-planar device of the non-planar device portion and a second gate-to-source/drain contact distance is defined for the planar FET of the MV/HV transistor portion. In general, and in various embodiments, the second gate-to-source/drain contact distance may be greater than the first gate-to-source/drain contact distance. However, due to the high exposure resolution in the first direction, the second gate-to-source/drain contact distance may be decreased (e.g., as compared to the second gate-to-source/drain contact distance in existing implementations) to save additional substrate area. Further, in some cases, a width of the source/drain contact of the rotated planar FET of the MV/HV transistor portion may be increased to provide reduced resistance. The various embodiments disclosed herein may be implemented without the need for an extra mask or extra process. In addition, the disclosed embodiments are robust, cost-effective, provide improved design flexibility, reduced interconnect routing, reduced substrate area coverage, reduced device resistance, and they are fully compatible with existing non-planar device process technology.

Thus, one of the embodiments of the present disclosure described a semiconductor device including a first device region of a substrate having a non-planar device. In some embodiments, the non-planar device includes a first active region extending in a first direction, an isolation feature extending in the first direction and disposed alongside the first active region, and a first gate including a gate dielectric layer, the first gate extending in a second direction over the first active region and the isolation feature, the second direction different from the first direction. In some embodiments, the semiconductor device further includes a second device region of the substrate having a first device, where the first device includes a second active region extending in the second direction and a second gate extending in the first direction. In some embodiments, a dielectric constant of the gate dielectric layer is greater than a dielectric constant of the isolation feature. In some embodiments, the non-planar device is configured to be operated at a same or lower voltage than the first device.

In another of the embodiments, discussed is a semiconductor device including a low-voltage (LV) transistor region having a first active region extending in a first direction in a top-down view, a second active region extending in the first direction in the top-down view, an isolation feature disposed between the first and second active regions and extending in the first direction in the top-down view, and a first gate extending in a second direction, in the top-down view, over the first active region, the isolation feature, and the second active region, where the second direction is different from the first direction. In some embodiments, the semiconductor device further includes a medium-voltage (MV)/high-voltage (HV) transistor region disposed on a same substrate as the LV transistor region, the MV/HV transistor region including a third active region extending in the second direction and a second gate extending in the first direction, in the top-down view. In some embodiments, first source/drain regions are disposed on the first and second active regions and on either side of the first gate, where, in a cross-section view, first source/drain contacts are electrically coupled to respective ones of the first source/drain regions by way of an interposing silicide layer, and where an electrical conductivity of the silicide layer is greater than an electrical conductivity of the first source/drain regions.

In yet another of the embodiments, discussed is a method including fabricating a first device in a first region of a substrate, where the first device includes a first active region extending in a first direction, an isolation feature extending in the first direction and disposed alongside the first active region, and a first gate structure including a gate dielectric layer, the first gate structure extending in a second direction over the first active region and the isolation feature, the second direction different from the first direction. In some embodiments, the method further includes after fabricating the first device, fabricating a second device in a second region of the substrate, where the second device includes a second active region extending in the second direction and a second gate structure extending in the first direction. In some embodiments, at least one of the first device and the second device is a non-planar device. In some embodiments, a dielectric constant of the gate dielectric layer is greater than a dielectric constant of the isolation feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a first device region of a substrate including a non-planar device, wherein the non-planar device includes a first active region extending in a first direction, an isolation feature extending in the first direction and disposed alongside the first active region, and a first gate including a gate dielectric layer, the first gate extending in a second direction over the first active region and the isolation feature, the second direction different from the first direction; and
a second device region of the substrate including a first device, wherein the first device includes a second active region extending in the second direction and a second gate extending in the first direction;
wherein a dielectric constant of the gate dielectric layer is greater than a dielectric constant of the isolation feature; and
wherein the non-planar device is configured to be operated at a same or lower voltage than the first device.

2. The semiconductor device of claim 1, wherein the first device is a planar device or another non-planar device.

3. The semiconductor device of claim 1, wherein the first direction is perpendicular to the second direction.

4. The semiconductor device of claim 1, wherein the first device is a planar device, and wherein a first distance between the first gate and a first adjacent source/drain contact of the non-planar device is different than a second distance between the second gate and a second adjacent source/drain contact of the planar device.

5. The semiconductor device of claim 4, wherein the first distance is less than the second distance.

6. The semiconductor device of claim 1, wherein the first device is a planar device, wherein the non-planar device further includes first source/drain contacts extending in the second direction, wherein the planar device further includes second source/drain contacts extending in the first direction, and wherein a first width of the first source/drain contacts along the first direction is different than a second width of the second source/drain contacts along the second direction.

7. The semiconductor device of claim 6, wherein the first width is less than the second width.

8. The semiconductor device of claim 1, wherein the non-planar device includes a fin field-effect transistor (FinFET) or a gate-all-around (GAA) transistor, and wherein the first device includes a planar field-effect transistor (planar FET).

9. The semiconductor device of claim 1, wherein the second device region includes the first device and a second device, wherein the first and second devices include first and second planar devices, respectively, wherein the second planar device includes a third active region extending in the first direction, and wherein the second planar device includes a third gate extending in the second direction.

10. A semiconductor device, comprising:
a first transistor region including a first active region extending in a first direction in a top-down view, a second active region extending in the first direction in the top-down view, an isolation feature disposed between the first and second active regions and extending in the first direction in the top-down view, and a first gate extending in a second direction, in the top-down view, over the first active region, the isolation feature, and the second active region, wherein the second direction is different from the first direction; and
a second transistor region disposed on a same substrate as the first transistor region, the second transistor region including a third active region extending in the second direction and a second gate extending in the first direction, in the top-down view;
wherein a first transistor in the first transistor region has a lower threshold voltage than a second transistor in the second transistor region, wherein first source/drain regions are disposed on the first and second active regions and on either side of the first gate, wherein, in a cross-section view, first source/drain contacts are electrically coupled to respective ones of the first source/drain regions by way of an interposing silicide layer, and wherein an electrical conductivity of the silicide layer is greater than an electrical conductivity of the first source/drain regions.

11. The semiconductor device of claim 10, wherein the first transistor region includes a non-planar transistor, and wherein the MV/HIV-second transistor region includes a planar field-effect transistor (planar FET).

12. The semiconductor device of claim 10, wherein the first direction is perpendicular to the second direction.

13. The semiconductor device of claim 10, wherein second source/drain regions are disposed on the third active region and on either side of the second gate, wherein second source/drain contacts are electrically coupled to respective ones of the second source/drain regions, wherein the first source/drain contacts extend in the second direction, wherein the second source/drain contacts extend in the first direction, and wherein a first width of the first source/drain contacts along the first direction is different than a second width of the second source/drain contacts along the second direction.

14. The semiconductor device of claim 13, wherein the first width is less than the second width.

15. The semiconductor device of claim 10, wherein a first distance between the first gate and a first source/drain contact coupled to a respective source/drain region of the first source/drain regions is different than a second distance between the second gate and a second source/drain contact coupled to another respective source/drain of second source/drain regions disposed on the third active region and on either side of the second gate.

16. The semiconductor device of claim 15, wherein the first distance is less than the second distance.

17. A method, comprising:
fabricating a first device in a first region of a substrate, wherein the first device includes a first active region extending in a first direction, an isolation feature extending in the first direction and disposed alongside the first active region, and a first gate structure including a gate dielectric layer, the first gate structure extending in a second direction over the first active region and the isolation feature, the second direction different from the first direction; and
after fabricating the first device, fabricating a second device in a second region of the substrate, wherein the second device includes a second active region extending in the second direction and a second gate structure extending in the first direction;
wherein at least one of the first device and the second device is a non-planar device; and
wherein a dielectric constant of the gate dielectric layer is greater than a dielectric constant of the isolation feature.

18. The method of claim 17, wherein the first device is the non-planar device, and wherein the second device is a planar device or another non-planar device.

19. The method of claim 17, wherein the non-planar device includes a fin field-effect transistor (FinFET) or a gate-all-around (GAA) transistor.

20. The method of claim 17, further comprising:
after fabricating the second device, simultaneously forming multilayer interconnect features for each of the first device and the second device.
